(19) United States
(12) Patent Application Publication
(10) Pub. No.: US 2026/0304831 A1
(43) Pub. Date: Oct. 1, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Akihiro KOYAMA, Tokyo (JP); Toshiaki IWAMATSU, Tokyo (JP)

(73) Assignee: Mitsubishi Electric Corporation, Tokyo (JP)

(21) Appl. No.: 19/100,954

(22) PCT Filed: Sep. 7, 2022
(86) PCT No.: PCT/JP2022/033581

§ 371 Date: Feb. 4, 2025

(51) Int. Cl. H10D 30/66; H10D 30/01; H10D 62/10; H10D 64/00

(52) U.S. Cl. CPC H10D 30/668; H10D 30/0297; H10D 30/665; H10D 64/111; H10D 62/102

(57) ABSTRACT

A semiconductor device includes a gate trench formed in an active region, a gate insulating film and a gate electrode layer formed in the gate trench, a gate wiring electrode formed on the interlayer insulating film covering the gate electrode layer, and an outer trench formed in a drift layer in a terminal region. Formed in the outer trench are a potential fixing layer covering an upper end corner part of the outer trench and an insulating layer formed on the potential fixing layer. The gate insulating film and the gate electrode layer extends to an inner side of the outer trench, and the gate electrode layer is connected to the gate wiring electrode through a contact hole formed in the interlayer insulating film in the outer trench.

### TECHNICAL FIELD

The present disclosure relates to a trench gate-type semiconductor device and a manufacturing method thereof, and particular to a structure of a gate electrode on a side of an outer periphery of the semiconductor device.

### BACKGROUND ART

A semiconductor device having a trench gate structure such as an insulated gate bipolar transistor (IGBT) or an insulated gate metal oxide semiconductor field effect transistor (MOSFET) is used for electrical power control of an in-vehicle apparatus or an industrial apparatus, for example.

Provided to the semiconductor device having the trench gate structure is “a gate leading part” in which a trench into which a gate electrode is embedded (referred to as “gate trench” hereinafter) extends from an active region in which main current flows to a terminal region on an outer side of the active region. Although drain voltage is low when the semiconductor device is in an ON state, voltage is applied to the gate electrode; thus, electrical field occurring in a gate insulating film gets large, and tends to be concentrated particularly in an upper end corner part of the gate trench.

Disclosed in Patent Document 1 described hereinafter is a technique of forming a gate insulating film in contact with a thick field insulating film formed by local oxidation of silicon (LOCOS) in a gate trench in a gate leading part, thereby reducing electrical field concentration in an upper end corner part of the gate trench.

Disclosed in Patent Document 2 described hereinafter is a technique of providing a field plate electrode together with a gate electrode in a gate trench in a gate leading part and setting potential of the field plate electrode to gate potential or source potential.

### PRIOR ART DOCUMENTS

### Patent Document(s)

Patent Document 1: Japanese Patent Application Laid-Open No. 2001-102572

Patent Document 2: Japanese Patent Application Laid-Open No. 2011-199109

### SUMMARY

### Problem to be Solved by the Invention

Even when withstand voltage of the gate insulating film of the gate leading part is improved by the field insulating film as with Patent Document 1, in a case where the upper end corner part of the gate trench has a canopy part which is out of a rectangular shape, for example, the field insulating film having a small thickness is locally formed; thus, an effect of improving the withstand voltage of the gate insulating film is not sufficiently obtained.

In a case where the potential of the field plate electrode is the gate potential in the gate leading part disclosed in Patent Document 2, when a thickness of the gate insulating film is not sufficiently large, there is a possibility that breakdown of the gate insulating film occurs in the upper end corner part of the gate trench. In the meanwhile, in a case where the potential of the field plate electrode is the source potential, there is a possibility that gate-source leakage current occurs through the insulating film between the gate electrode and the field plate electrode. There is also a possibility that the gate insulating film having a small thickness is locally formed on the field plate electrode depending on a shape of the field plate electrode, and such a configuration causes breakdown of the gate insulating film.

The present disclosure is to solve the above problems, and an object is to provide a semiconductor device capable of preventing breakdown of a gate insulating film in an upper end corner part of a gate trench of a gate leading part.

### Means to Solve the Problem

A semiconductor device according to the present disclosure includes: a drift layer of a first conductivity type; a well region of a second conductivity type formed on a surface portion of the drift layer; an impurity region of a first conductivity type formed on a surface portion of the well region; a gate trench passing through the impurity region and the well region in an active region to reach the drift layer; a gate insulating film formed to have contact with an inner surface of the gate trench; a gate electrode film formed on the gate insulating film; an interlayer insulating film covering the gate electrode layer; a gate wiring electrode formed on the interlayer insulating film and connected to the gate electrode layer; an outer trench formed in the drift layer in a terminal region on an outer side of the active region; a potential fixing layer formed in the outer trench to cover an upper end corner part of the outer trench; and an insulating film formed on the potential fixing layer, wherein the gate insulating film and the gate electrode film extend to an inner side of the outer trench of the terminal region, and the gate electrode layer is connected to the gate wiring electrode through a contact hole formed in the interlayer insulating film in the outer trench.

### Effects of the Invention

According to the present disclosure, since the upper end corner part of the outer trench is covered by the potential fixing layer and insulating layer, the gate electrode and the gate insulating film led to the outer trench are formed on the insulating layer, and are isolated from the upper end corner part of the outer trench. Thus, prevented is breakdown of the gate insulating film by electrical field concentration caused by a shape of the upper end corner part of the outer trench.

These and other objects, features, aspects and advantages of the present disclosure will become more apparent from the following detailed description when taken in conjunction with the accompanying diagrams.

### BRIEF DESCRIPTION OF DRAWINGS

FIG. 1 is a schematic plan view illustrating a schematic configuration of a semiconductor device according to an embodiment 1.

FIG. 2 is a schematic view illustrating a schematic configuration of a boundary part between an active region 50 and a terminal region 60 in the semiconductor device according to the embodiment 1.

FIG. 3 is a schematic cross-sectional view illustrating a schematic configuration of a semiconductor device along an A1-A2 line in FIG. 2 according to the embodiment 1.

FIG. 4 is a schematic cross-sectional view illustrating a schematic configuration of the semiconductor device along a B1-B2 line in FIG. 2 according to the embodiment 1.

FIG. 5 is a schematic cross-sectional view illustrating a schematic configuration of the semiconductor device along a C1-C2 line in FIG. 2 according to the embodiment 1.

FIG. 6 is a schematic cross-sectional view illustrating a schematic configuration of the semiconductor device along a D1-D2 line in FIG. 2 according to the embodiment 1.

FIG. 7 is a partial cross-sectional view illustrating a method of manufacturing the semiconductor device along the B1-B2 line in FIG. 2 according to the embodiment 1.

FIG. 8 is a partial cross-sectional view illustrating a method of manufacturing the semiconductor device along the B1-B2 line in FIG. 2 according to the embodiment 1.

FIG. 9 is a partial cross-sectional view illustrating a method of manufacturing the semiconductor device along the B1-B2 line in FIG. 2 according to the embodiment 1.

FIG. 10 is a partial cross-sectional view illustrating a method of manufacturing the semiconductor device along the B1-B2 line in FIG. 2 according to the embodiment 1.

FIG. 11 is a partial cross-sectional view illustrating a method of manufacturing the semiconductor device along the B1-B2 line in FIG. 2 according to the embodiment 1.

FIG. 12 is a partial cross-sectional view illustrating a method of manufacturing the semiconductor device along the B1-B2 line in FIG. 2 according to the embodiment 1.

FIG. 13 is a partial cross-sectional view illustrating a method of manufacturing the semiconductor device along a D1-D2 line in FIG. 2 according to the embodiment 1.

FIG. 14 is a partial cross-sectional view illustrating a method of manufacturing the semiconductor device along the D1-D2 line in FIG. 2 according to the embodiment 1.

FIG. 15 is a partial cross-sectional view illustrating a method of manufacturing the semiconductor device along the D1-D2 line in FIG. 2 according to the embodiment 1.

FIG. 16 is a partial cross-sectional view illustrating a method of manufacturing the semiconductor device along the D1-D2 line in FIG. 2 according to the embodiment 1.

FIG. 17 is a partial cross-sectional view illustrating a method of manufacturing the semiconductor device along the D1-D2 line in FIG. 2 according to the embodiment 1.

FIG. 18 is a partial cross-sectional view illustrating a method of manufacturing the semiconductor device along the D1-D2 line in FIG. 2 according to the embodiment 1.

FIG. 19 is a partial cross-sectional view illustrating a method of manufacturing the semiconductor device along the D1-D2 line in FIG. 2 according to the embodiment 1.

FIG. 20 is a partial cross-sectional view illustrating a method of manufacturing the semiconductor device along the D1-D2 line in FIG. 2 according to the embodiment 1.

FIG. 21 is a partial cross-sectional view illustrating a method of manufacturing the semiconductor device along the D1-D2 line in FIG. 2 according to the embodiment 1.

FIG. 22 is a schematic cross-sectional view illustrating a schematic configuration of a semiconductor device along the B1-B2 line in FIG. 2 according to an embodiment 2.

FIG. 23 is a schematic cross-sectional view illustrating a schematic configuration of the semiconductor device along a C1-C2 line in FIG. 2 according to the embodiment 2.

FIG. 24 is a partial cross-sectional view illustrating a method of manufacturing the semiconductor device along the B1-B2 line in FIG. 2 according to the embodiment 2.

FIG. 25 is a partial cross-sectional view illustrating a method of manufacturing the semiconductor device along the B1-B2 line in FIG. 2 according to the embodiment 2.

FIG. 26 is a partial cross-sectional view illustrating a method of manufacturing the semiconductor device along the B1-B2 line in FIG. 2 according to the embodiment 2.

FIG. 27 is a partial cross-sectional view illustrating a method of manufacturing the semiconductor device along the B1-B2 line in FIG. 2 according to the embodiment 2.

FIG. 28 is a partial cross-sectional view illustrating a method of manufacturing the semiconductor device along the B1-B2 line in FIG. 2 according to the embodiment 2.

FIG. 29 is a partial cross-sectional view illustrating a method of manufacturing the semiconductor device along the B1-B2 line in FIG. 2 according to the embodiment 2.

FIG. 30 is a partial cross-sectional view illustrating a method of manufacturing the semiconductor device along the B1-B2 line in FIG. 2 according to the embodiment 2.

FIG. 31 is a partial cross-sectional view illustrating a method of manufacturing the semiconductor device along the C1-C2 line in FIG. 2 according to the embodiment 2.

FIG. 32 is a partial cross-sectional view illustrating a method of manufacturing the semiconductor device along the C1-C2 line in FIG. 2 according to the embodiment 2.

FIG. 33 is a partial cross-sectional view illustrating a method of manufacturing the semiconductor device along the C1-C2 line in FIG. 2 according to the embodiment 2.

FIG. 34 is a partial cross-sectional view illustrating a method of manufacturing the semiconductor device along the C1-C2 line in FIG. 2 according to the embodiment 2.

FIG. 35 is a partial cross-sectional view illustrating a method of manufacturing the semiconductor device along the C1-C2 line in FIG. 2 according to the embodiment 2.

FIG. 36 is a partial cross-sectional view illustrating a method of manufacturing the semiconductor device along the C1-C2 line in FIG. 2 according to the embodiment 2.

FIG. 37 is a partial cross-sectional view illustrating a method of manufacturing the semiconductor device along the C1-C2 line in FIG. 2 according to the embodiment 2.

FIG. 38 is a schematic plan view illustrating a schematic configuration of a semiconductor device according to an embodiment 3.

FIG. 39 is a schematic view illustrating a schematic configuration of the semiconductor device according to the embodiment 3.

FIG. 40 is a schematic cross-sectional view illustrating a schematic configuration of the semiconductor device along a D1-D2 line in FIG. 39 according to the embodiment 3.

FIG. 41 is a schematic view illustrating a schematic configuration of a semiconductor device according to an embodiment 4.

FIG. 42 is a schematic cross-sectional view illustrating a schematic configuration of the semiconductor device along a D1-D2 line in FIG. 41 according to the embodiment 4.

FIG. 43 is a schematic cross-sectional view illustrating a schematic configuration of a semiconductor device along the D1-D2 line in FIG. 2 according to an embodiment 5.

FIG. 44 is a schematic cross-sectional view illustrating a schematic configuration of the semiconductor device along the D1-D2 line in FIG. 39 according to the embodiment 5.

FIG. 45 is a schematic cross-sectional view illustrating a schematic configuration of the semiconductor device along the D1-D2 line in FIG. 41 according to the embodiment 5.

FIG. 46 is a schematic cross-sectional view illustrating a schematic configuration of a semiconductor device along the B1-B2 line in FIG. 2, FIG. 39, or FIG. 41 according to an embodiment 6.

FIG. 47 is a schematic cross-sectional view illustrating a schematic configuration of a semiconductor device along the D1-D2 line in FIG. 2 according to an embodiment 6.

FIG. 48 is a schematic cross-sectional view illustrating a schematic configuration of the semiconductor device along the D1-D2 line in FIG. 39 according to the embodiment 6.

FIG. 49 is a schematic cross-sectional view illustrating a schematic configuration of the semiconductor device along the D1-D2 line in FIG. 41 according to the embodiment 6.

### DESCRIPTION OF EMBODIMENT(S)

Embodiments of a technique according to the present disclosure are described hereinafter with reference to the diagrams. The diagrams are schematically illustrated; thus, a size and a mutual relationship of positions of images each illustrated in different diagrams are not necessarily illustrated accurately, but can be appropriately changed. The same reference numerals are assigned to similar constituent elements, and the same applies to names and functions thereof. Thus, a detailed description thereof may be omitted in some cases.

Used in the description are terms each indicating a specific position and direction such as “upper side”, “lower side”, “lateral side”, “bottom”, “front”, or “rear”, for example; however, these terms are used for convenience of easy understanding of the embodiments, and do not relate to a position and a direction in an actual use.

The “one” constituent element described in the embodiments may be “one or more” constituent elements so far as consistent with the embodiments. Further, the constituent elements are conceptual units. Thus, one constituent element may include multiple structures, and one constituent element may correspond to part of a structure.

In the embodiments hereinafter, a first conductivity type of a semiconductor is an n type and a second conductivity type thereof is a p type, but reversely, it is also applicable that the first conductivity type is the p type and the second conductivity type is the n type. Although a MOSFET is described as an example of the semiconductor device, the semiconductor device may be an IGBT. In the description hereinafter, a material of a semiconductor substrate and a drift layer is silicon carbide (SiC) as wide bandgap semiconductor having a larger bandgap than silicon, but may be silicon, the other wide bandgap semiconductor such as gallium nitride or diamond, for example, or a combination thereof.

In the description hereinafter, “an impurity concentration” indicates a peak value of an impurity concentration in each region.

### Embodiment 1

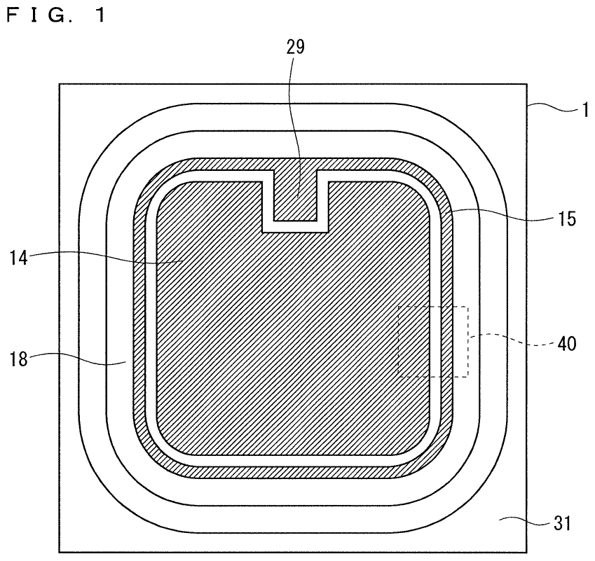

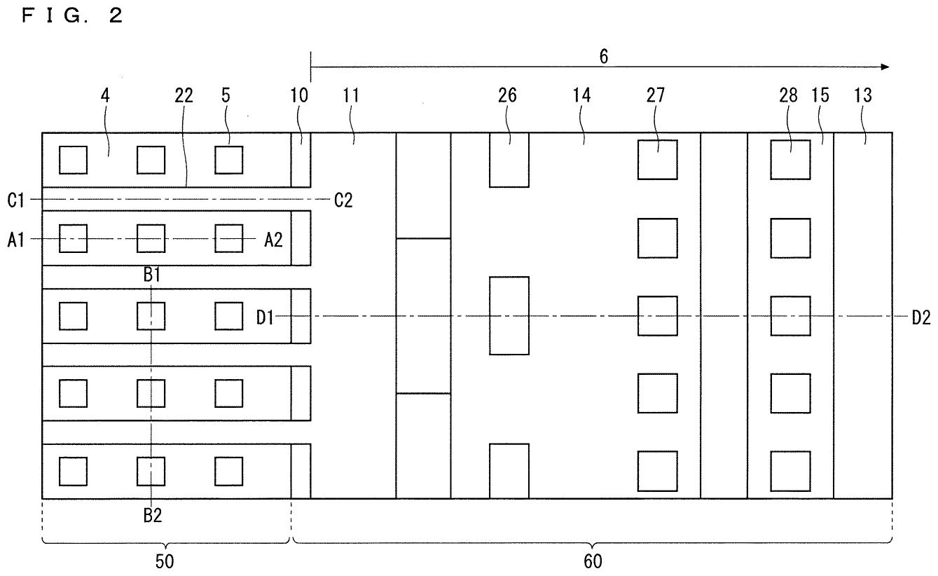

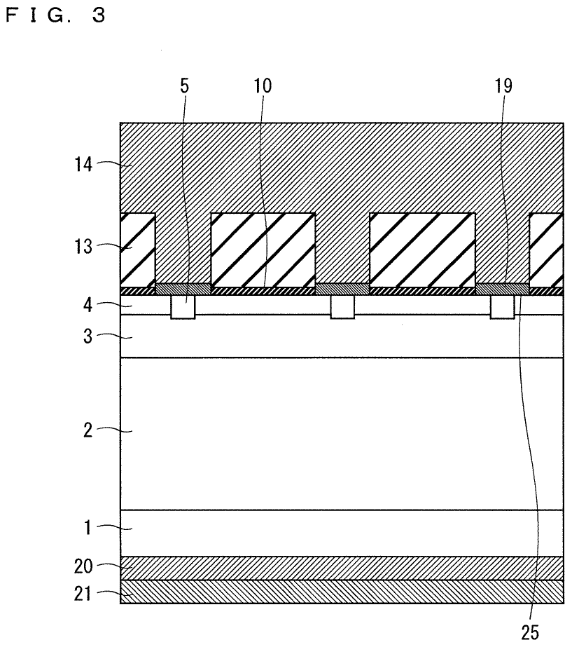

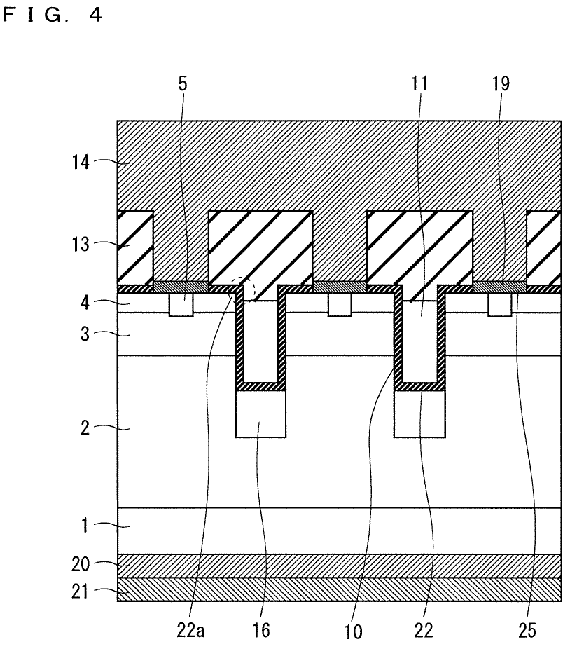

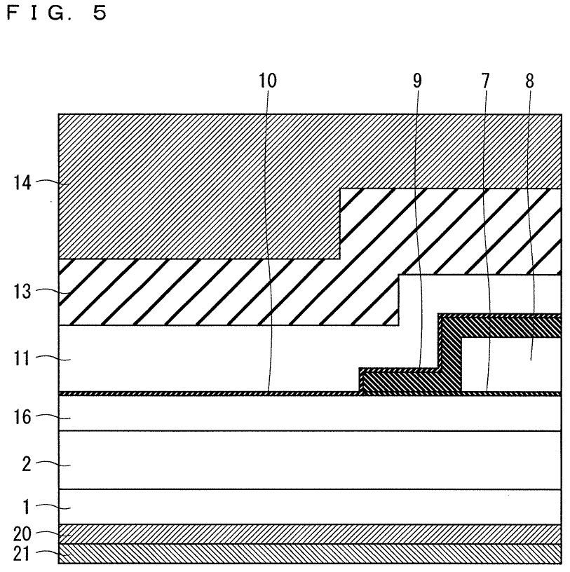

FIG. 1 is a schematic plan view illustrating a schematic configuration of a semiconductor device according to an embodiment 1. FIG. 2 is a schematic view illustrating a schematic configuration of a boundary part between an active region 50 and a terminal region 60 in the semiconductor device according to the embodiment 1, and illustrates a portion of a region 40 surrounded by a broken line in FIG. 1. Illustration of an interlayer insulating film 13, a front surface electrode 14, and a front surface ohmic electrode 19, for example, is omitted for simplifying the description in FIG. 2. Furthermore, FIG. 3 to FIG. 6 are schematic diagrams each illustrating a cross-sectional configuration of the semiconductor device according to the embodiment 1, FIG. 3 illustrates a cross-sectional view along an A1-A2 line in FIG. 2, FIG. 4 is a cross-sectional view along a B1-B2 line in FIG. 2, FIG. 5 is a cross-sectional view along a C1-C2 line in FIG. 2, and FIG. 6 is a cross-sectional view along a D1-D2 line in FIG. 2.

The active region 50 is a region in which current flows by formation of a channel in the semiconductor device in an ON state, and the terminal region 60 is a region around the active region 50. The terminal region 60 is provided to surround the active region 50 on an outer surrounding part of a chip of the semiconductor device, and formed in the terminal region 60 are a p-type terminal electrical field relaxation region 18 such as a field limiting ring (FLR) and an n-type channel stop region 31 suppressing extension of a deletion layer to an end part of the chip.

A gate trench 22 is provided to a drift layer 2 of the active region 50, and an outer trench 6 corresponding to a gate trench of a gate leading part is provided to the drift layer 2 of the terminal region 60. As illustrated in FIG. 2, the gate trench 22 is formed into a stripe shape in a plan view. A cell is formed in each of a plurality of regions sectioned by the gate trench 22 in the active region 50. Although FIG. 2 illustrates the example of the plurality of quadrangular cells disposed in a stripe form, a shape of the cell may be a circular shape or a polygonal shape such as a hexagonal shape, and the cell may be disposed in a checkerboard pattern or a zigzag pattern.

As illustrated in FIG. 3 to FIG. 6, the drift layer 2, a well region 3, an impurity region 4, and a contact region 5, for example, are provided to a front side of the semiconductor substrate 1 constituting the semiconductor device. Provided to the active region 50 are the gate trench 22, a trench bottom surface electrical field relaxation region 16, a gate insulating film 10, and a gate electrode layer 11. Provided to the terminal region 60 are the outer trench 6, the trench bottom surface electrical field relaxation region 16, a trench bottom surface high concentration well region 17, a terminal electrical field relaxation region 18, an underlay insulating film 7, a potential fixing layer 8, an insulating layer 9, the gate insulating film 10, the gate electrode layer 11, a field insulating film 12, and a gate wiring electrode 15. The gate electrode layer 11 formed in the outer trench 6 in the terminal region 60 extends to surround the gate trench 22 in a plan view. The front surface ohmic electrode 19, the interlayer insulating film 13, and the front surface electrode 14 are provided to both the active region 50 and the terminal region 60 in common on a front surface of the semiconductor substrate 1. A back surface ohmic electrode 20 and a back surface electrode 21 are provided to both the active region 50 and the terminal region 60 in common on a back surface of the semiconductor substrate 1.

The drift layer 2 is provided on the semiconductor substrate 1 made of n-type silicon carbide, and is made of n-type silicon carbide. It is sufficient that an n-type impurity of the drift layer 2 is nitrogen or phosphorus, and an impurity concentration of the drift layer 2 is approximately equal to or larger than 1×10¹⁴ cm⁻³ and equal to or smaller than 1×10¹⁸ cm⁻³. It is sufficient that a thickness of the drift layer 2 is approximately equal to or larger than 5 μm and equal to or smaller than 300 μm.

The well region 3 is a p-type region provided on a surface portion of the drift layer 2, and is made of silicon carbide. It is sufficient that a p-type impurity of the well region 3 is aluminum, boron, or gallium, and an impurity concentration of the well region 3 is approximately equal to or larger than 1×10¹⁵ cm⁻³ and equal to or smaller than 1×1020cm-3. Herein, the impurity concentration of the well region 3 may be or may not be constant in a depth direction. It is sufficient that a thickness of the well region 3 is approximately equal to or larger than 0.3 μm and equal to or smaller than 3 μm.

The impurity region 4 is an n-type region provided on a surface portion of the well region 3, and is made of silicon carbide. It is sufficient that an n-type impurity of the impurity region 4 is nitrogen or phosphorus, and an impurity concentration of the impurity region 4 is approximately equal to or larger than 1×10¹⁷ cm³ and equal to or smaller than 1×10²² cm⁻³. It is sufficient that a thickness of the impurity region 4 is equal to or smaller than that of the well region 3.

The contact region 5 is a p-type region provided to the surface portion of the well region 3 and having a higher impurity concentration than the well region 3, and is made of silicon carbide. It is sufficient that a p-type impurity of the contact region 5 is aluminum, boron, or gallium, and an impurity concentration of the contact region 5 is approximately equal to or larger than 1×10¹⁸ cm⁻³ and equal to or smaller than 1×10²² cm⁻³. It is sufficient that a thickness of the contact region 5 is equal to or smaller than that of the well region 3.

A contact hole 25 (referred to as “the source contact hole 25” hereinafter) reaching the impurity region 4 and the contact region 5 is formed in the interlayer insulating film 13, and the front surface ohmic electrode 19 connected to the impurity region 4 and the contact region 5 is formed in a bottom of the source contact hole 25. The impurity region 4 and the contact region 5 are electrically connected to the front surface electrode 14 as a main electrode through the front surface ohmic electrode 19 in the source contact hole 25.

Herein, the contact region 5 is connected to the impurity region 4 by the front surface ohmic electrode 19. When the contact region 5 is formed, a route connected to the front surface ohmic electrode 19 from the well region 3 via the contact region 5 is formed, and electrical connection from the well region 3 to the front surface ohmic electrode 19 is preferably achieved. The contact region 5 may be omitted.

The gate trench 22 passes through the well region 3 from the surface of the impurity region 4 to reach the drift layer 2. As illustrated in FIG. 2, the gate trench 22 is provided to the active region 50 in a stripe form (that is to say, in a form of a plurality of lines parallel to each other). When the gate trench 22 is provided in the stripe form, in a case where the semiconductor device is a trench gate-type silicon carbide MOSFET, a plane such as (1-100) plane having high channel mobility can be used as a channel, and characteristics of the semiconductor device can be improved. The gate trench 22 extends in a direction of the terminal region 60. In the description hereinafter, the direction in which the gate trench 22 extends is referred to as “the extension direction” of the gate trench 22.

It is sufficient that a width of the gate trench 22 is approximately equal to or larger than 0.5 μm and equal to or smaller than 10 μm. When the gate trench 22 has a tapered shape in a cross-sectional view, the width of the gate trench 22 indicates a width of a widest part of the tapered shape. It is sufficient that a depth of the gate trench 22 is approximately equal to or larger than 0.5 μm and equal to or smaller than 6 μm.

The trench bottom surface electrical field relaxation region 16 is a p-type region provided to a lower side of a bottom surface of the gate trench 22, and is made of silicon carbide. The trench bottom surface electrical field relaxation region 16 has a conductivity type opposite to that of the drift layer 2, and has a function of relaxing electrical field on the gate insulating film 10 formed on the bottom surface of the gate trench 22 in the semiconductor device in an operation state. Breakdown of the gate insulating film 10 is thereby prevented. It is sufficient that a depth of the trench bottom surface electrical field relaxation region 16 is approximately equal to or larger than 1 μm and equal to or smaller than 3.0 μm toward a lower side from the bottom surface of the gate trench 22. The trench bottom surface electrical field relaxation region 16 may have contact with the bottom surface of the gate trench 22. It is sufficient that a p-type impurity of the trench bottom surface electrical field relaxation region 16 is aluminum, boron, or gallium, and an impurity concentration of the trench bottom surface electrical field relaxation region 16 is approximately equal to or larger than 1×10¹⁵ cm⁻³ and equal to or smaller than 1×10¹⁹ cm^{-3.}

The outer trench 6 is a wide trench formed to have substantially the same depth as the gate trench 22 in the terminal region 60. The trench bottom surface electrical field relaxation region 16 is also provided to a lower side of the outer trench 6.

The trench bottom surface high concentration well region 17 has a conductivity type opposite to that of the drift layer 2, and is provided in the trench bottom surface electrical field relaxation region 16 on the lower side of the outer trench 6. The trench bottom surface high concentration well region 17 is a p-type region having a high concentration than the trench bottom surface electrical field relaxation region 16, and is made of silicon carbide. A contact hole 26 (referred to as “the outer surrounding part well region contact hole 26” hereinafter) reaching the trench bottom surface high concentration well region 17 is formed in the interlayer insulating film 13, and the front surface ohmic electrode 19 connected to the trench bottom surface high concentration well region 17 is formed in a bottom of the outer surrounding part well region contact hole 26. The trench bottom surface electrical field relaxation region 16 is electrically connected to the front surface electrode 14 through the trench bottom surface high concentration well region 17 and the front surface ohmic electrode 19 in the outer surrounding part well region contact hole 26.

The trench bottom surface high concentration well region 17 has an effect of reducing contact resistance between the trench bottom surface electrical field relaxation region 16 and the front surface ohmic electrode 19 and an effect of reducing sheet resistance on a surface of the trench bottom surface electrical field relaxation region 16. It is sufficient that a depth of the trench bottom surface high concentration well region 17 is approximately equal to or larger than 0.1 μm and equal to or smaller than 2.0 μm toward a lower side from the bottom surface of the outer trench 6. The trench bottom surface high concentration well region 17 may have contact with the bottom surface of the outer trench 6. It is sufficient that a p-type impurity of the trench bottom surface high concentration well region 17 is aluminum, boron, or gallium, and an impurity concentration of the trench bottom surface high concentration well region 17 is approximately equal to or larger than 1×10¹⁸ cm⁻³ and equal to or smaller than 1×10²² cm⁻³.

The terminal electrical field relaxation region 18 is a p-type electrical field relaxation region continuously or intermittently formed to surround the active region 50, and is a field limiting ring (FLR), for example. The terminal electrical field relaxation region 18 is formed by ion-implanting aluminum, boron, or gallium, for example, from the surface of the drift layer 2 to a depth of approximately 0.2 μm to 3 μm so as not to exceed the depth of the drift layer 2, for example. It is sufficient that a p-type impurity of the terminal electrical field relaxation region 18 is higher than the impurity concentration of the drift layer 2, and is equal to or larger than 1×10¹⁵ cm⁻³ and equal to or smaller than 1×10¹⁹ cm⁻³.

The field insulating film 12 is formed to have contact with the surface of the drift layer 2 from an inner side of the outer trench 6 to an end part of the chip. The field insulating film 12 can be made of an insulative material such as silicon dioxide. A thickness of the field insulating film 12 can be equal to or larger than 0.1 μm and equal to or smaller than 5.0 μm, for example.

The underlay insulating film 7 is formed to cover the inner part of the outer trench 6 and an upper end corner part 6a (referred to as “the outer trench upper end corner part 6a” hereinafter), and has contact with the well region 3, the drift layer 2, the trench bottom surface electrical field relaxation region 16, and the trench bottom surface high concentration well region 17. A part of the underlay insulating film 7 is also formed on the field insulating film 12. The underlay insulating film 7 is made of an insulative material such as silicon dioxide. A thickness of the underlay insulating film 7 is approximately equal to or larger than 10 nm and equal to or smaller than 1000 nm, for example.

The potential fixing layer 8 is a layer having conductivity such as polysilicon, is formed on the underlay insulating film 7, and covers the inner part of the outer trench 6 and the outer trench upper end corner part 6a via the underlay insulating film 7. A part of the potential fixing layer 8 is also formed on the field insulating film 12. In the present embodiment, the potential fixing layer 8 is a first polysilicon layer made of polysilicon. A contact hole 27 (referred to as “the potential fixing layer connection contact hole 27” hereinafter) reaching the potential fixing layer 8 on the field insulating film 12 is formed in the interlayer insulating film 13, and the potential fixing layer 8 is connected to the front surface electrode 14 through the potential fixing layer connection contact hole 27. Since potential of the front surface electrode 14 is source potential, potential of the potential fixing layer 8 is also source potential. The potential fixing layer 8 has a thickness larger than the gate insulating film 10, and preferably has a thickness more than three times as large as the gate insulating film 10.

The insulating layer 9 is formed to cover the potential fixing layer 8. The insulating layer 9 suppresses flowing of gate leakage current between the potential fixing layer 8 and the gate electrode layer 11. The insulating layer 9 is made of an insulative material such as silicon dioxide. A thickness of the insulating layer 9 is approximately equal to or larger than 10 nm and equal to or smaller than 1000 nm, for example, and preferably has a thickness equal to or larger than the gate insulating film 10.

The gate insulating film 10 is formed to have contact with an inner surface of the gate trench 22, a part of the surface of the drift layer 2, the insulating layer 9, and the field insulating film 12, and is made of silicon dioxide. A thickness of the gate insulating film 10 can be approximately equal to or larger than 10 nm and equal to or smaller than 200 nm, for example.

The gate electrode layer 11 is formed on the gate insulating film 10 in the gate trench 22 and on the gate insulating film 10 formed on the insulating layer 9 in the outer trench 6. In this manner, the gate insulating film 10 and the gate electrode layer 11 extend from an inner side of the gate trench 22 to an inner side of the outer trench 6. A height of an upper end of the gate electrode layer 11 in the gate trench 22 is preferably equal to or smaller than a surface position of the drift layer 2, and is more preferably lower than the surface position of the drift layer 2. In the present embodiment, the gate electrode layer 11 is a second polysilicon layer made of polysilicon. The gate electrode layer 11 formed in the terminal region 60 has a thickness larger than the gate insulating film 10, for example. A contact hole 28 (referred to as “the gate contact hole 28” hereinafter) reaching the gate electrode layer 11 is formed in the interlayer insulating film 13, and the gate electrode layer 11 is connected to the gate wiring electrode 15 connected to a gate electrode pad 29 via the gate contact hole 28.

The front surface electrode 14, the gate wiring electrode 15, and the gate electrode pad 29 are formed on the interlayer insulating film 13, and are made of a metal material such as aluminum, for example. The front surface electrode 14, the gate wiring electrode 15, and the gate electrode pad 29 are disposed to be isolated from each other.

The back surface ohmic electrode 20 is formed on the back surface of the semiconductor substrate 1, and is made up of a reaction product of a metal film made of nickel as a main component and the semiconductor substrate 1 such as nickel silicide, for example. The back surface electrode 21 is formed to have contact with the back surface ohmic electrode 20, and is made of titanium, nickel, silver, gold, or aluminum, for example.

The semiconductor device according to the embodiment 1 is made up of the constituent elements described above.

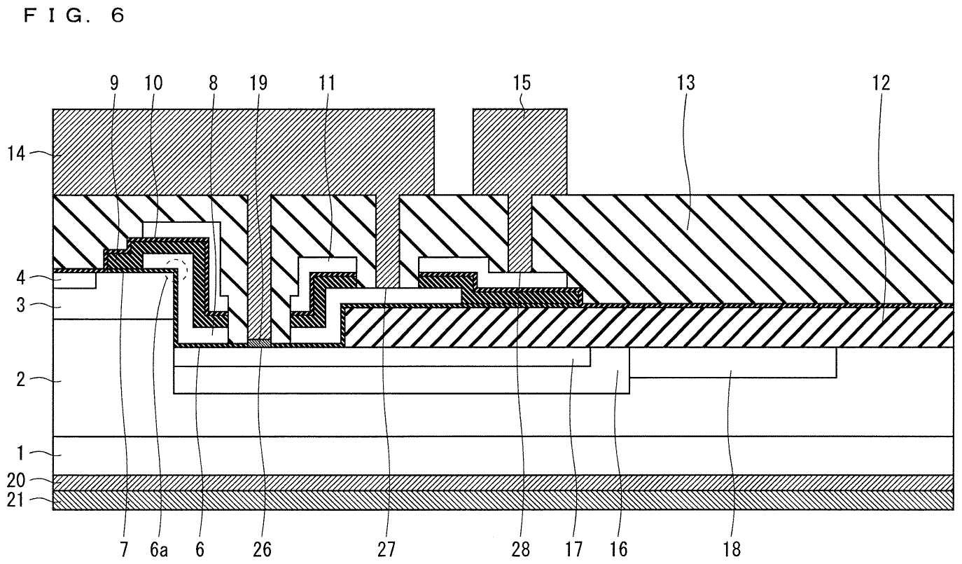

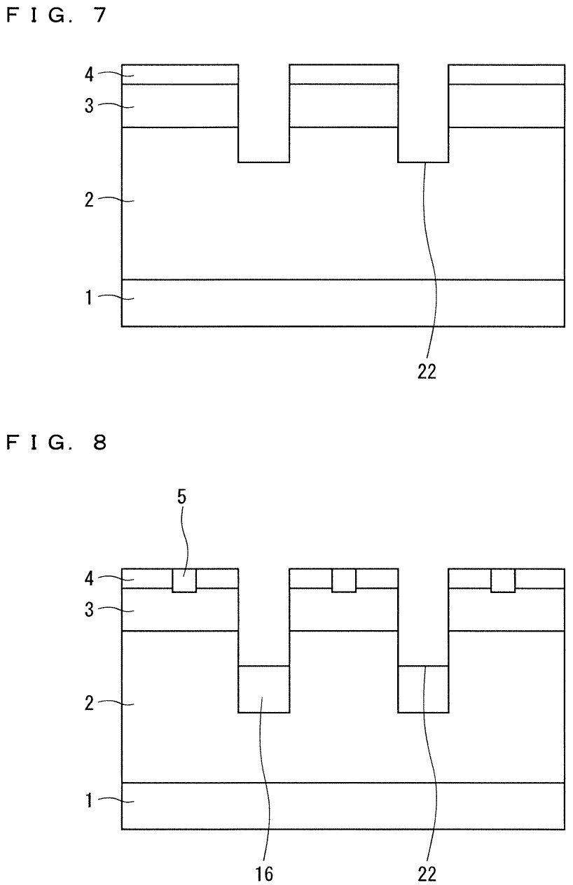

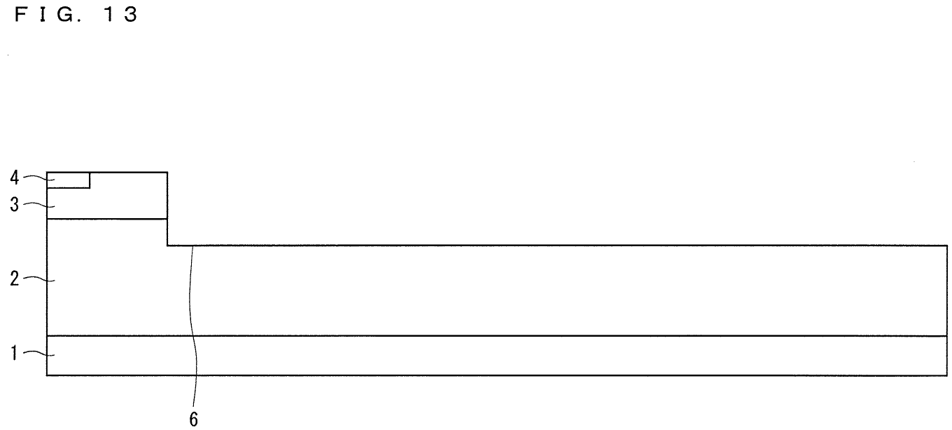

A method of manufacturing the semiconductor device according to the embodiment 1 is described next with reference to FIG. 7 to FIG. 21. FIG. 7 to FIG. 21 are explanation diagrams of each manufacturing stage of the semiconductor device. Herein, FIG. 7 to FIG. 12 correspond to a cross section along a B1-B2 line in FIG. 2, and FIG. 13 to FIG. 21 correspond to a cross section along a D1-D2 line in FIG. 2.

Firstly, the n-type silicon carbide semiconductor substrate 1 having a 4H polytype is prepared, and the n-type drift layer 2 is epitaxially grown thereon by chemical vapor deposition (CVD) method. At this time, the impurity concentration of the n-type drift layer 2 is within a range of 1×10¹⁴ cm⁻³ to 1×10¹⁸ cm⁻³, and the thickness of the drift layer 2 is 5 μm to 300 μm.

Subsequently, aluminum, boron, or gallium is ion-implanted using a resist mask formed on the drift layer 2 by photolithography processing to form the p-type well region 3 on the surface portion of the drift layer 2. The well region 3 may be formed by an epitaxial growth.

Subsequently, nitrogen or phosphorus is ion-implanted using a resist mask formed on the well region 3 by photolithography processing to form the n-type impurity region 4 on the surface portion of the well region 3.

Subsequently, a silicon dioxide film having a thickness of approximately 1 μm to 2 μm is formed on the well region 3 and the impurity region 4, and an etching mask in which formation regions where the gate trench 22 and the outer trench 6 are formed are opened is formed by reactive ion etching (RIE). Then, when the gate trench 22 and the outer trench 6 are formed by RIE, states in FIG. 7 and FIG. 13 are achieved.

Next, after a resist mask covering a part of the outer trench 6 is formed by photolithography processing while the etching mask is left, aluminum, boron, or gallium is ion-implanted from a side of the surface of the drift layer 2 to form the trench bottom surface electrical field relaxation region 16 on a lower side of the gate trench 22 and the outer trench 6.

Subsequently, after the etching mask and the resist mask described above are removed and a resist mask is formed by photolithography processing, aluminum, boron, or gallium is ion-implanted from the side of the surface of the drift layer 2 to form the terminal electrical field relaxation region 18 in the terminal region 60.

Subsequently, after a resist mask is formed by photolithography processing, aluminum, boron, or gallium is ion-implanted to form the p-type contact region 5 on the surface portion of the well region 3 and the trench bottom surface high concentration well region 17 is formed on the surface portion of the trench bottom surface electrical field relaxation region 16. A heating temperature of the semiconductor substrate 1 in this ion implantation is preferably equal to or higher than 150° C. When the heating temperature is equal to or higher than 150° C., electrical resistance of the contact region 5 can be reduced, and resistive loss in the operation state of the semiconductor device can be reduced.

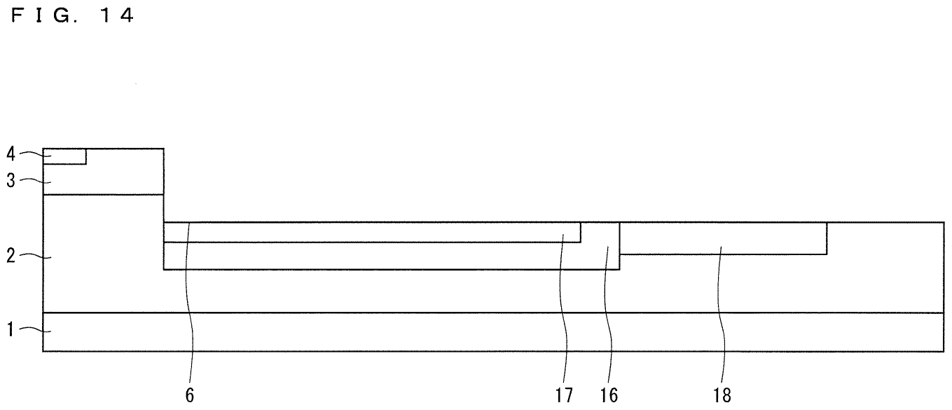

Subsequently, anneal processing is performed after the etching mask is removed to activate the impurity which has been ion-implanted. The anneal processing is performed in inactive gas atmosphere of argon, for example, or in vacuum at a temperature of approximately 1500° C. to 1900° C. for approximately 30 seconds to 1 hour. Herein, a carbon film may be formed on the semiconductor substrate 1 before the anneal processing to prevent deterioration of silicon carbide caused by heating at a high temperature, that is to say, a surface roughness. Accordingly, states in FIG. 8 and FIG. 14 are achieved.

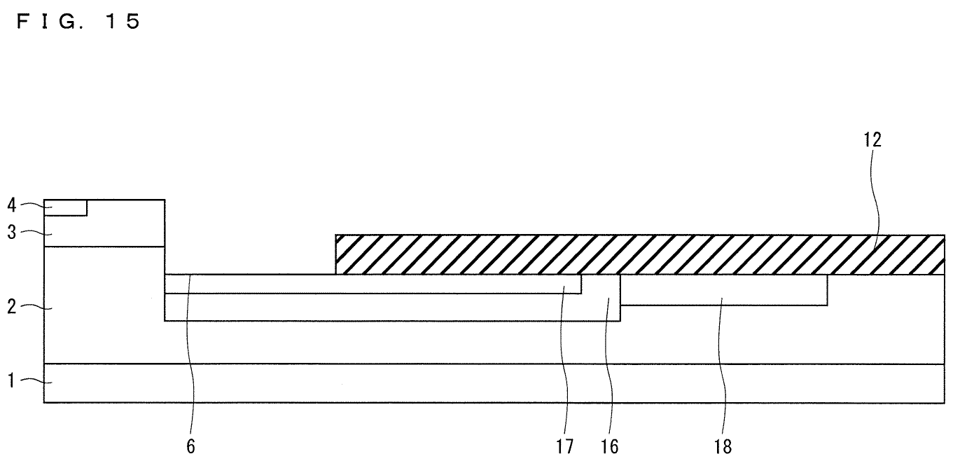

Next, an insulating film of silicon dioxide serving as the field insulating film 12 is formed by CVD method, for example, and a resist mask is formed on this insulating film by photolithography processing. Then, an opening is formed in the insulating film by etching to form the field insulating film 12, and the resist mask is removed. Accordingly, a state in FIG. 15 is achieved.

Next, the inner part of the outer trench 6 and the upper end corner part are covered by thermal oxidation method or CVD method, for example, and the underlay insulating film 7 is formed to have contact with the well region 3, the drift layer 2, the trench bottom surface electrical field relaxation region 16, and the trench bottom surface high concentration well region 17. A part of the underlay insulating film 7 is also formed on the field insulating film 12.

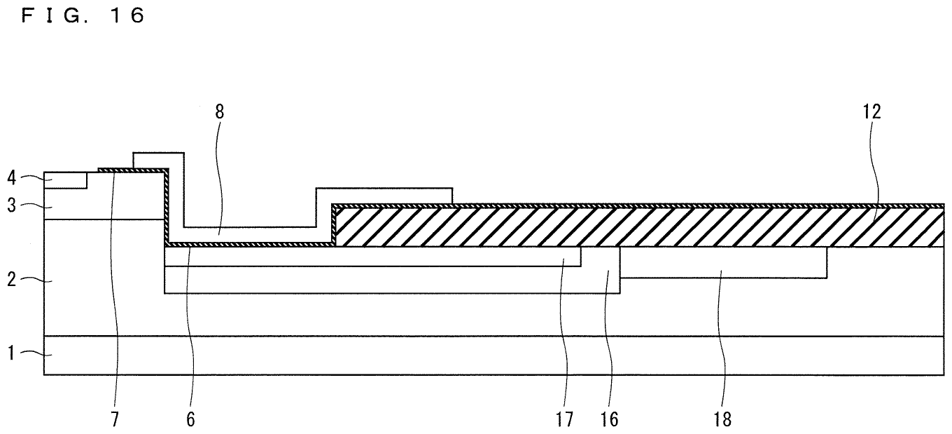

Subsequently, a conductive material of polysilicon, for example, serving as the potential fixing layer 8 is formed on the underlay insulating film 7 by CVD method, for example, and a resist mask is formed on polysilicon by photolithography processing. Then, polysilicon is etched to form the potential fixing layer 8 in the terminal region 60. A part of the potential fixing layer 8 is also formed on the field insulating film 12. At this time, polysilicon in the active region 50 is wholly removed by etching until the underlay insulating film 7 is exposed by an etch-back process. Subsequently, the resist mask is removed. Accordingly, a state in FIG. 16 is achieved.

Next, a layer of silicon dioxide, for example, serving as the insulating film 9 is formed to cover the potential fixing layer 8 by CVD method, for example. When the potential fixing layer 8 is made of polysilicon as a material, this layer of silicon dioxide, for example, may be formed by thermally oxidizing the surface of the potential fixing layer 8. Next, a resist mask is formed by photolithography processing, and the insulating layer 9 is formed by etching. The underlay insulating film 7 and the insulating layer 9 in the gate trench 22 in the active region 50 are wholly removed by etching to expose the drift layer 2. Accordingly, a state in FIG. 17 is achieved.

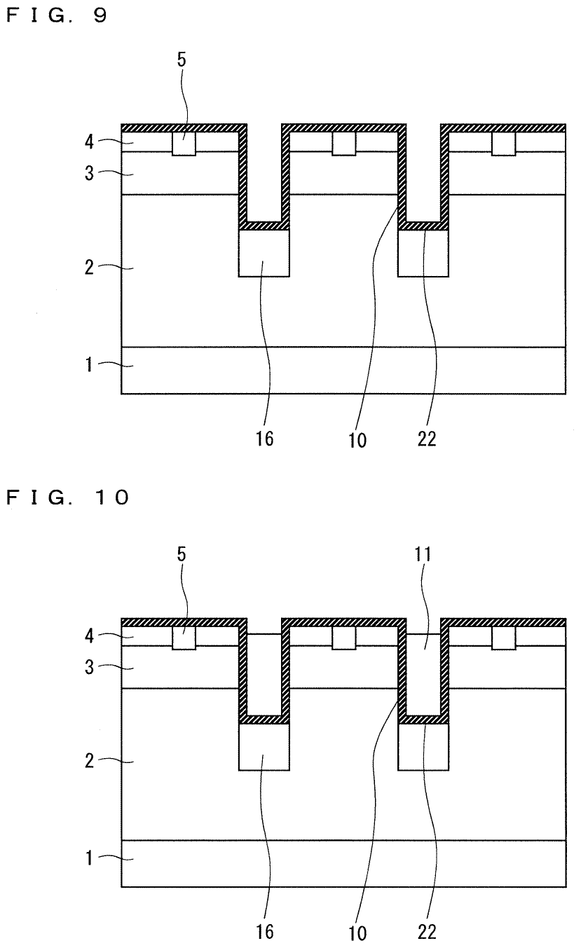

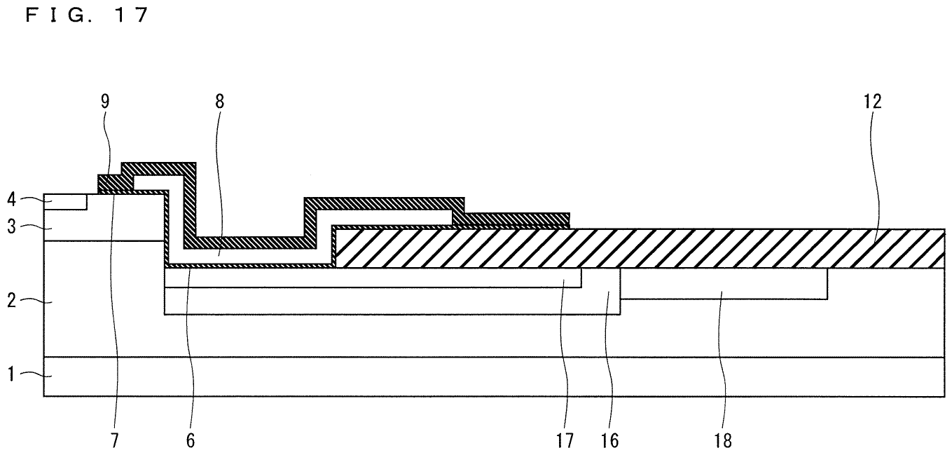

Next, the gate insulating film 10 is formed on the surface of the drift layer 2, the inner surface of the gate trench 22, and the insulating layer 9 and the field insulating film 12 in the terminal region 60 by thermal oxidation method or CVD method, for example. Accordingly, states in FIG. 9 and FIG. 18 are achieved.

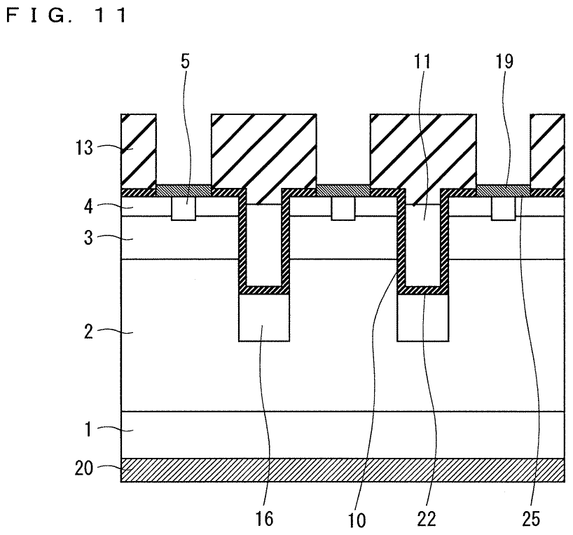

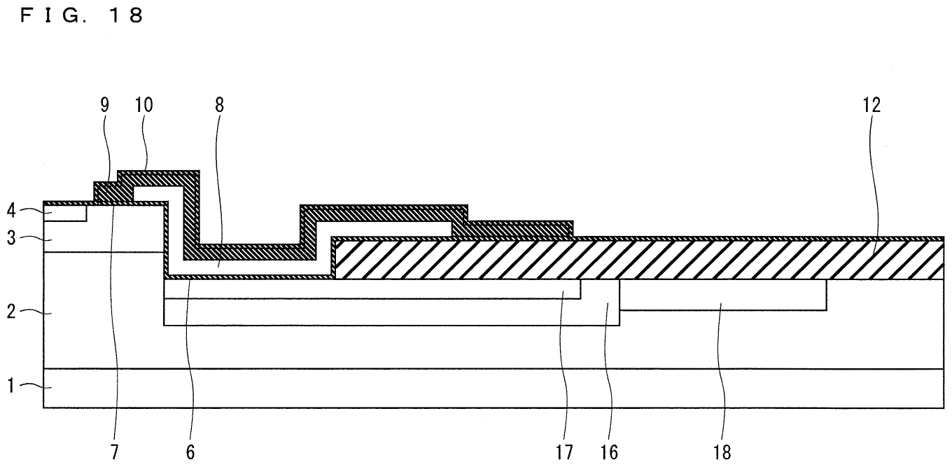

Then, a conductive material of polysilicon, for example, serving as the gate electrode layer 11 is formed by CVD method, for example, and a resist mask is formed on polysilicon by photolithography processing. Subsequently, polysilicon is etched to form the gate electrode layer 11, and the resist mask is removed. At this time, polysilicon is etched by an etch-back process in the active region 50 so that an upper end of the gate electrode layer 11 is located to be equal or lower than the surface position of the drift layer 2 in the gate trench 22. Accordingly, states in FIG. 10 and FIG. 19 are achieved.

Next, the interlayer insulating film 13 is formed by decompression CVD method, for example, and a resist mask is formed on the interlayer insulating film 13 by photolithography processing. Subsequently, the interlayer insulating film 13 is etched to form the source contact hole 25 reaching the impurity region 4 and the contact region 5 and the outer surrounding part well region contact hole 26 reaching the trench bottom surface high concentration well region 17.

Then, a metal film made of Ni, for example, as a main component is formed on the impurity region 4 and the contact region 5 exposed to the source contact hole 25 and the trench bottom surface high concentration well region 17 exposed to the outer surrounding part well region contact hole 26, and anneal processing is performed to form the front surface ohmic electrode 19. Then, the metal film on the interlayer insulating film 13 is removed by etching, and the resist mask is removed.

Furthermore, a metal film made of Ni, for example, as a main component is formed on the back surface of the semiconductor substrate 1, and anneal processing is performed to form the back surface ohmic electrode 20. Herein, it is sufficient that a heating temperature in each anneal processing is approximately equal to or higher than 600° C. and equal to or smaller than 1100° C.

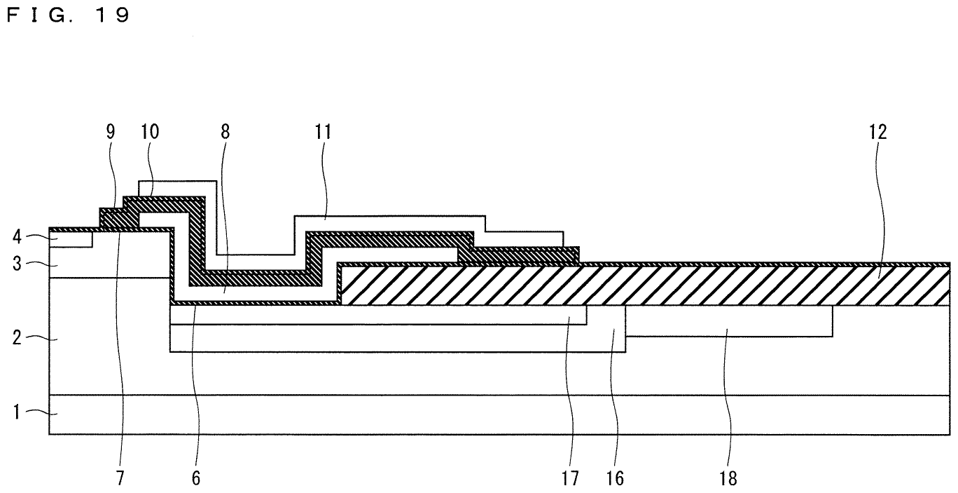

Next, a resist mask is formed on the interlayer insulating film 13 by photolithography processing, and the interlayer insulating film 13 is etched to form the potential fixing layer connection contact hole 27 reaching the potential fixing layer 8 and the gate contact hole 28 reaching the gate electrode layer 11, and the resist mask is removed. Accordingly, states in FIG. 11 and FIG. 20 are achieved.

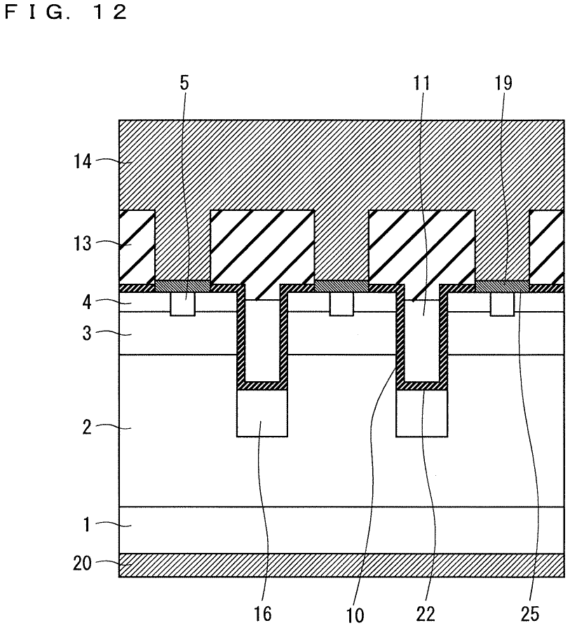

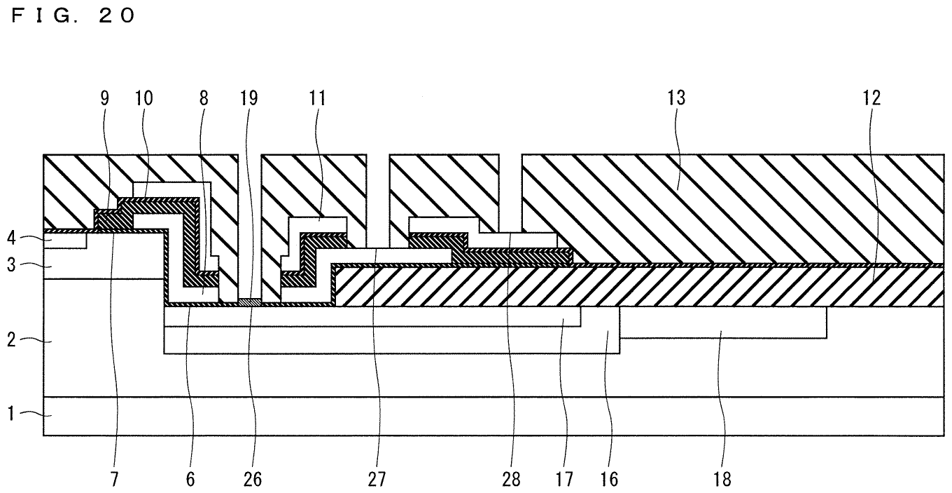

Then, a metal film of aluminum, for example, is formed on the interlayer insulating film 13 and the front surface ohmic electrode 19 and inner sides of the potential fixing layer connection contact hole 27 and the gate contact hole 28 by sputtering method or evaporation method, for example, and a resist mask is formed on the metal film by photolithography processing. Subsequently, patterning is performed on the metal film by etching to form the front surface electrode 14, the gate wiring electrode 15, and the gate electrode pad 29, and then the resist mask is removed. Accordingly, states in FIG. 12 and FIG. 21 are achieved.

Finally, the back surface electrode 21 is formed on the back surface ohmic electrode 20 by sputtering method or evaporation method, for example, and the structure of the semiconductor device illustrated in FIG. 4 and FIG. 6 is completed.

The channel stop region 31 suppressing extension of a depletion layer to an end part of the semiconductor device may be provided to the terminal region 60 as illustrated in FIG. 1. The channel stop region 31 is an n-type region provided on a side closer to an outer periphery than the outer trench 6, and is made of silicon carbide. It is sufficient that an n-type impurity of the channel stop region 31 is nitrogen or phosphorus, and an impurity concentration of the channel stop region 31 is approximately equal to or larger than 1×10¹⁷ cm⁻³ and equal to or smaller than 1×10²² cm⁻³. A thickness of the channel stop region 31 may be the same as or different from that of the impurity region 4. It is sufficient that the channel stop region 31 is formed by ion implantation. The channel stop region 31 may be formed at the same time as the impurity region 4 using the resist mask for providing the impurity region 4, of may also be formed before or after forming the impurity region 4. When the channel stop region 31 is formed at the same time as the impurity region 4, it is sufficient that the channel stop region 31 and the impurity region 4 are formed after forming the gate trench 22 and the outer trench 6, for example.

An order of performing the process of forming the well region 3 and the process of forming the impurity region 4 may be switched. It is applicable as the method of forming the well region 3 and the impurity region 4 that after an n-type impurity is ion-implanted into the surface portion of the well region 3, a resist mask is formed thereon by photolithography processing, and a p-type impurity is ion-implanted into a position other than the impurity region 4 to form the well region 3.

In the manufacturing method described above, the thickness of the etching mask and the RIE process are adjusted so that the etching mask is left after the gate trench 22 and the outer trench 6 are formed, and the trench bottom surface electrical field relaxation region 16 is formed by ion implantation using the etching mask which has been left and the resist mask formed by photolithography processing. However, it is also applicable that the etching mask is not left but is removed and the trench bottom surface electrical field relaxation region 16 is formed by ion implantation using only the resist mask formed by photolithography processing.

The trench bottom surface electrical field relaxation region 16 located on the lower side of the outer trench 6 may be formed at the same time as the trench bottom surface electrical field relaxation region 16 located on the lower side of the gate trench 22, or may also be formed before or after forming the trench bottom surface electrical field relaxation region 16 located on the lower side of the gate trench 22. Furthermore, it is also applicable that a p-type impurity is ion-implanted in an oblique direction with respect to the gate trench 22, a p-type semiconductor layer is formed in the drift layer 2 having contact with a side surface of the gate trench 22, and the trench bottom surface electrical field relaxation region 16 and the well region 3 are electrically connected to each other via the semiconductor layer. When the trench bottom surface electrical field relaxation region 16 and the well region 3 are electrically connected to each other, the trench bottom surface electrical field relaxation region 16 is connected to the front surface electrode 14 and grounded via the well region 3 compared with a state where the trench bottom surface electrical field relaxation region 16 is in a floating state; thus, the frequency characteristics of the semiconductor device are improved.

Although described in the present embodiment is the example that the semiconductor device is the MOSFET, when the semiconductor device is the IGBT, it is sufficient that a conductivity type of the semiconductor substrate 1 is a p type, and the semiconductor substrate 1 may be ground to reduce the thickness thereof.

An operation of the semiconductor device according to the present embodiment is described next.

When gate voltage equal to or larger than a threshold value is applied between the gate electrode pad 29 and the front surface electrode 14, a channel is formed in the well region 3 facing the gate electrode layer 11, and electrons flows from the impurity region 4 to the drift layer 2. When voltage is applied between the front surface electrode 14 and the back surface electrode 21 and electrical field occurs, electrons reach the back surface electrode 21 through the drift layer 2 and the semiconductor substrate 1. That is to say, current flowing from the back surface electrode 21 toward the front surface electrode 14 occurs, and the semiconductor device enters an ON state.

Herein, when the gate insulating film 10 is formed to have contact with a surface and an inner side of each of the gate trench 22 and the outer trench 6, electrical field occurs in the gate insulating film 10 near an upper end corner part 22a (referred to as “the gate trench upper end corner part 22a” hereinafter) of the outer trench 6 and the outer trench upper end corner part 6a. However, in the active region 50, the gate electrode layer 11 is formed in a lower position than the gate trench upper end corner part 22a; thus, electrical field concentration caused by a shape of the gate trench upper end corner part 22a is suppressed, and breakdown of the gate insulating film 10 is prevented.

In the meanwhile, in the terminal region 60, the gate insulating film 10 is formed on the insulating film 9, and is isolated from the outer trench upper end corner part 6a; thus, prevented is breakdown of the gate insulating film 10 by electrical field concentration caused by a shape of the outer trench upper end corner part 6a. Although the outer trench upper end corner part 6a is covered by the underlay insulating film 7, the well region 3 and the potential fixing layer 8 have source potential, and moreover, the potential fixing layer 8 is insulated from the gate electrode layer 11 by the insulating layer 9 and the gate insulating film 10; thus, the underlay insulating film 7 of the outer trench upper end corner part 6a is not broken by gate voltage.

Herein, when the thickness of the potential fixing layer 8 is sufficiently large, since the potential fixing layer 8 covers the upper end corner part and the inner part of the outer trench 6 via the underlay insulating film 7, curvature of an upper part of the potential fixing layer 8 can be increased by a level difference of the outer trench 6. When the curvature of the upper part of the potential fixing layer 8 is increased, local reduction of the thickness of the insulating layer 9 and the gate insulating film 10 formed on the potential fixing layer 8 can be prevented, and an effect of preventing breakdown of the insulating layer 9 and the gate insulating film 10 caused by the electrical field concentration is further increased.

When the thickness of the insulating layer 9 is small, insulation between the potential fixing layer 8 and the gate electrode layer 11 is insufficient, and there is a possibility that gate-source leakage current increases as with the case where the potential of the field plate electrode is the source potential in Patent Document 2, and a region between the potential fixing layer 8 and the gate electrode layer 11 is broken by electrical field and is short-circuited. In order to prevent such a state, the thickness of the insulating layer 9 is preferably larger than that of the gate insulating film 10. According to such a configuration, the region between the potential fixing layer 8 and the gate electrode layer 11 can be insulated with a thickness twice or more as large as the gate insulating film 10, insulation properties between a source and a gate in the terminal region 60 can be increased more than the active region 50, gate-source leakage current in the terminal region 60 is suppressed, and further increased is an effect of preventing breakdown of the insulating layer 9 and the gate insulating film 10.

In the meanwhile, when voltage smaller than a threshold value is applied between the gate electrode pad 29 and the front surface electrode 14, a channel is not formed in the well region 3 facing the gate electrode layer 11, current flowing from the back surface electrode 21 toward the front surface electrode 14 does not occur, and the semiconductor device enters an OFF state. In the semiconductor device in the OFF state, voltage higher than that in the ON state is applied between the front surface electrode 14 and the back surface electrode 21, and a depletion layer extends from the well region 3 to the drift layer 2.

At this time, the depletion layer extends also from the trench bottom surface electrical field relaxation region 16 to the drift layer 2. Accordingly, electrical field occurring by the high voltage applied between the front surface electrode 14 and the back surface electrode 21 suppresses breakdown of the gate insulating film 10 in a bottom surface or a bottom surface corner part of each of the gate trench 22 and the outer trench 6.

When the state of the semiconductor device is switched from the OFF state to the ON state, voltage applied between the front surface electrode 14 and the back surface electrode 21 decreases, and the depletion layer extending to the drift layer 2 shrinks. The semiconductor device is operated to alternately repeat the ON state and the OFF state described above.

According to the semiconductor device according to the embodiment 1, breakdown of the gate insulating film 10 in the gate trench upper end corner part 22a and the outer trench upper end corner part 6a can be prevented.

### Embodiment 2

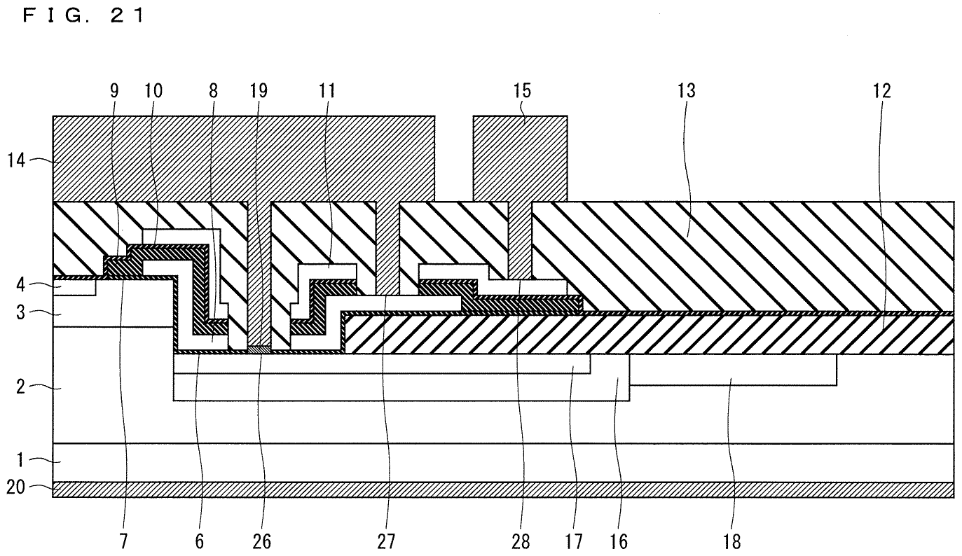

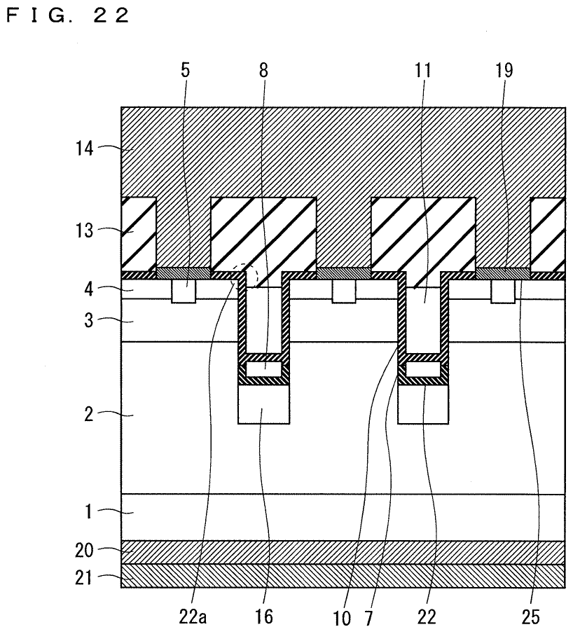

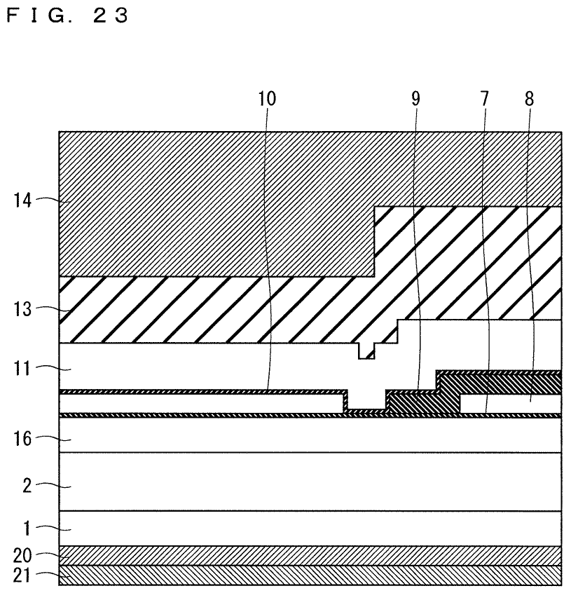

FIG. 22 and FIG. 23 are diagrams each illustrating a configuration of a semiconductor device according to an embodiment 2, FIG. 22 corresponds to a cross-sectional view along the B1-B2 line in FIG. 2, and FIG. 23 corresponds to a cross-sectional view along the C1-C2 line in FIG. 2. In the present embodiment, cross-sectional configurations along the A1-A2 line and D1-D2 line in FIG. 2 are similar to those according to the embodiment 1.

In the embodiment 2, the underlay insulating film 7 and the potential fixing layer 8 are provided below the gate insulating film 10 and the gate electrode layer 11 in the gate trench 22 in the active region 50. The underlay insulating film 7 is formed to have contact with the inner surface of the gate trench 22, and the potential fixing layer 8 is formed on the underlay insulating film 7 in the gate trench 22. The gate insulating film 10 is formed to have contact with the inner surface of the gate trench 22 and the upper surface of the potential fixing layer 8, and the gate electrode layer 11 is formed on the gate insulating film 10.

In the present embodiment, the potential of the potential fixing layer 8 formed in the gate trench is the floating potential. The underlay insulating film 7 is formed to have a larger thickness than the gate insulating film 10 to reduce influence of the electrical field occurring in the bottom surface of the gate trench 22 by the drain voltage.

In FIG. 22, the trench bottom surface electrical field relaxation region 16 is formed on the lower side of the gate trench 22, but may be omitted. When the trench bottom surface electrical field relaxation region 16 is not formed, electrical field occurring in the bottom surface of the gate trench 22 by the drain voltage in the semiconductor device in the OFF state is divided by the depletion layer formed between the well region 3 and the drift layer 2, the underlay insulating film 7, and the potential fixing layer 8. When a concentration of phosphorus in polysilicon of the potential fixing layer 8 is reduced, depletion of polysilicon is increased, and an electrical field relaxation effect can be increased.

When the trench bottom surface electrical field relaxation region 16 is not formed, resolved is current narrowing in the semiconductor device in the ON state caused by the depletion layer extending from the well region 3 to the drift layer 2 and the depletion layer extending from the trench bottom surface electrical field relaxation region 16 to the drift layer 2. Thus, an effect of improving ON characteristics is also obtained.

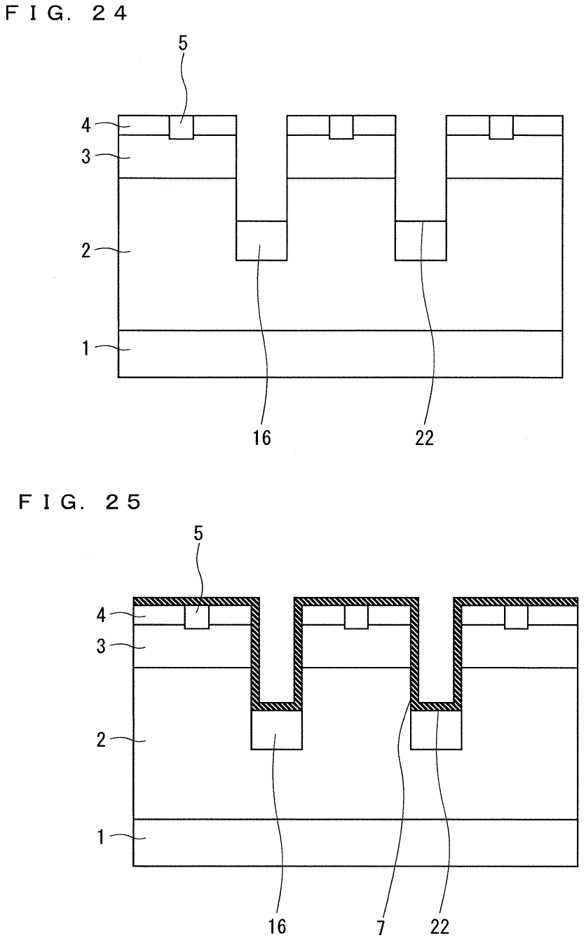

A method of manufacturing the semiconductor device according to the embodiment 2 is described next with reference to FIG. 24 to FIG. 37. FIG. 24 to FIG. 37 are explanation diagrams of each manufacturing stage of the semiconductor device. Herein, FIG. 24 to FIG. 30 correspond to a cross section along the B1-B2 line in FIG. 2, and FIG. 31 to FIG. 37 correspond to a cross section along the C1-C2 line in FIG. 2.

Firstly, in the manner similar to the embodiment 1, the n-type silicon carbide semiconductor substrate 1 having a 4H polytype is prepared, and the n-type drift layer 2 is epitaxially grown thereon by chemical vapor deposition (CVD) to form the well region 3, the impurity region 4, the gate trench 22, and the trench bottom surface electrical field relaxation region 16. Accordingly, states in FIG. 24 and FIG. 31 are achieved.

Next, an insulating film of silicon dioxide serving as the field insulating film 12 is formed by CVD method, for example, and a resist mask is formed on this insulating film by photolithography processing. Then, an opening is formed in the insulating film by etching to form the field insulating film 12, and the resist mask is removed.

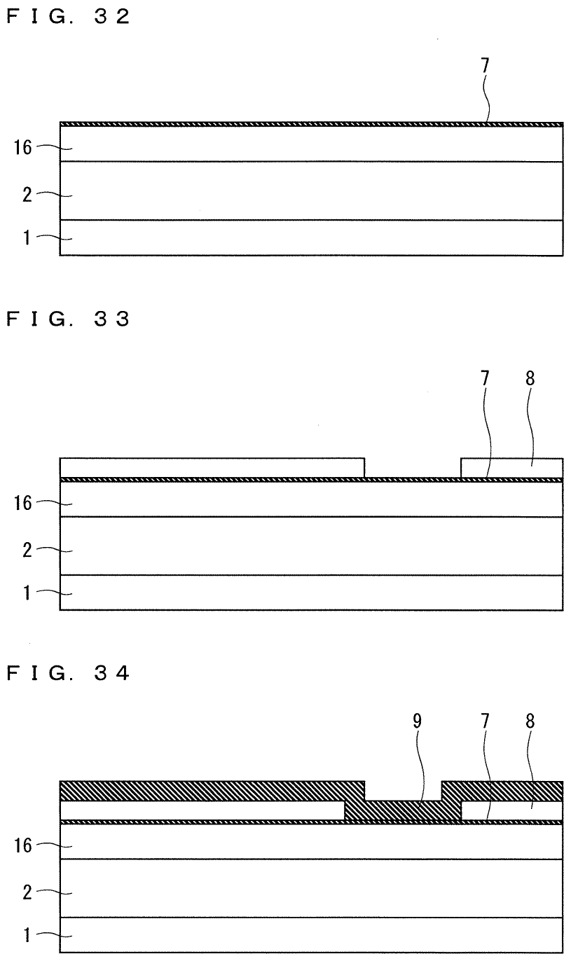

Then, the underlay insulating film 7 is formed by thermal oxidation method or CVD method, for example. Accordingly, states in FIG. 25 and FIG. 32 are achieved.

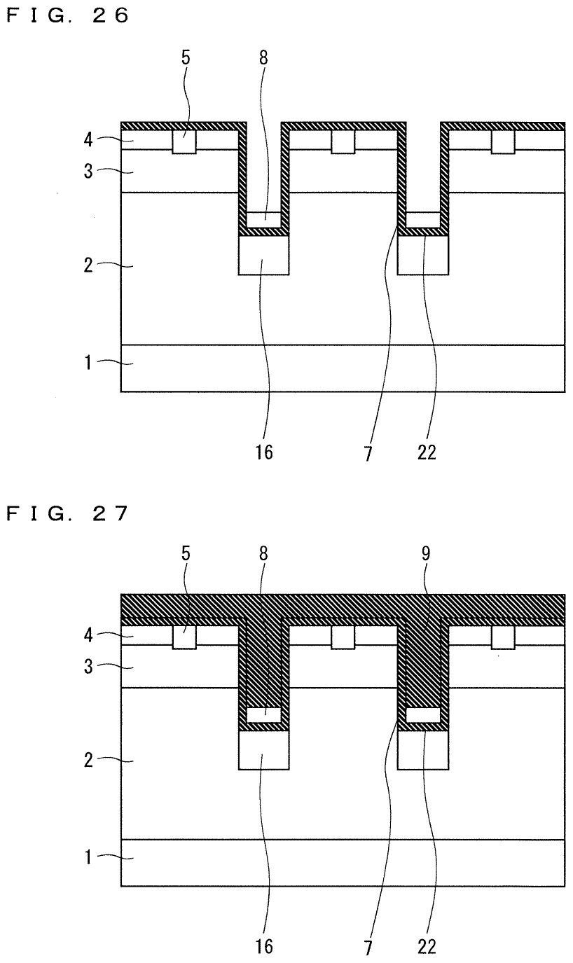

Subsequently, a conductive material of polysilicon, for example, serving as the potential fixing layer 8 is formed on the underlay insulating film 7 by CVD method, for example, and is etched so that a desired thickness is left in the gate trench 22 by an etch-back process. Subsequently, a resist mask is formed by photolithography processing, the potential fixing layer 8 in the active region 50 and the potential fixing layer 8 in the terminal region 60 are separated by etching so that the potential fixing layer 8 in the active region 50 has the floating potential, and the resist mask is removed. Accordingly, states in FIG. 26 and FIG. 33 are achieved.

Next, the insulating layer 9 of silicon dioxide, for example, is formed to cover the potential fixing layer 8 by CVD method, for example. When the potential fixing layer 8 is made of polysilicon as a material, the insulating layer 9 may be formed by thermally oxidizing the potential fixing layer 8. Accordingly, states in FIG. 27 and FIG. 34 are achieved.

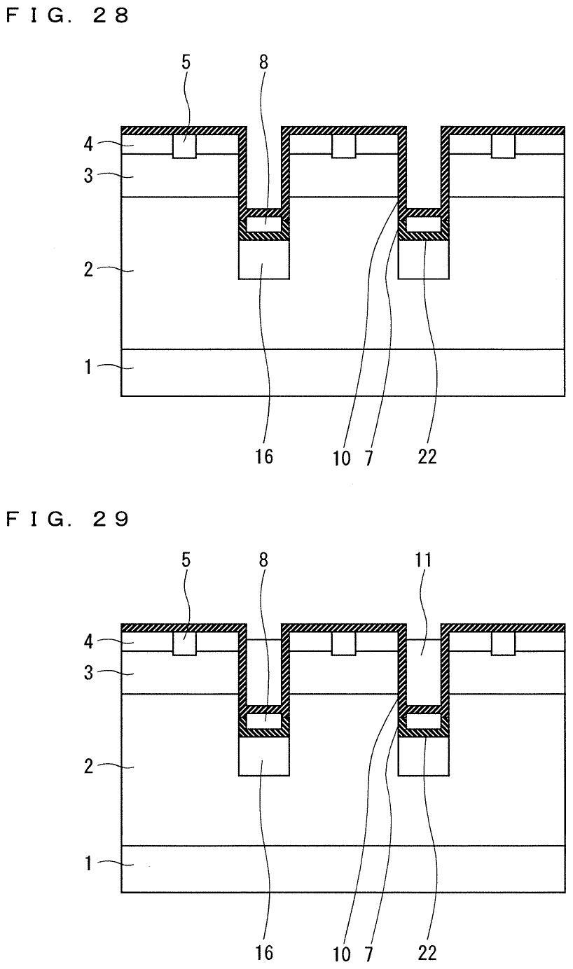

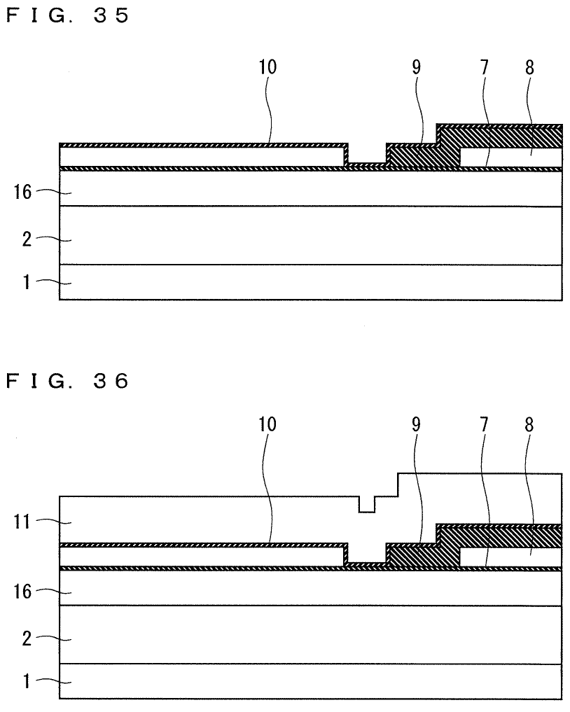

Next, a resist mask is formed by photolithography processing, and etching is performed until an upper side of a sidewall of the potential fixing layer 8 and an upper end part thereof in the gate trench 22 are exposed. Subsequently, the gate insulating film 10 is formed on the surface of the drift layer 2, the inner surface of the gate trench 22, and the insulating layer 9 by thermal oxidation method or CVD method, for example. Accordingly, states in FIG. 28 and FIG. 35 are achieved.

Then, a conductive material of polysilicon, for example, serving as the gate electrode layer 11 is formed by CVD method, for example, and a resist mask is formed on polysilicon by photolithography processing. Subsequently, polysilicon is etched to form the gate electrode layer 11, and the resist mask is removed. At this time, polysilicon is etched by an etch-back process in the active region 50 so that an upper end of the gate electrode layer 11 is located to be equal or lower than the surface position of the drift layer 2 in the gate trench 22. Accordingly, states in FIG. 29 and FIG. 36 are achieved.

Next, the interlayer insulating film 13 is formed by decompression CVD method, for example, and a resist mask is formed on the interlayer insulating film 13 by photolithography processing. Subsequently, the interlayer insulating film 13 is etched to form the source contact hole 25 reaching the impurity region 4 and the contact region 5 and the outer surrounding part well region contact hole 26 reaching the trench bottom surface high concentration well region 17.

Then, a metal film made of Ni, for example, as a main component is formed on the impurity region 4 and the contact region 5 exposed to the source contact hole 25 and the trench bottom surface high concentration well region 17 exposed to the outer surrounding part well region contact hole 26, and anneal processing is performed to form the front surface ohmic electrode 19. Then, the metal film on the interlayer insulating film 13 is removed by etching, and the resist mask is removed.

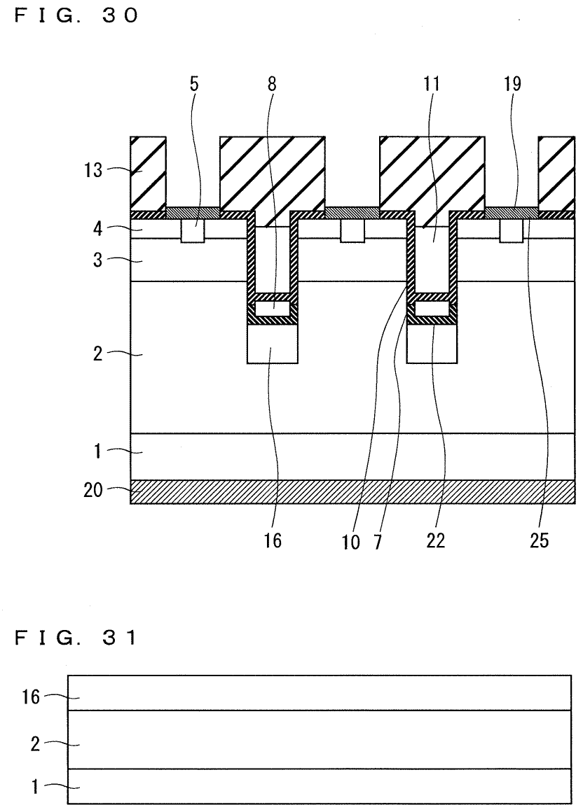

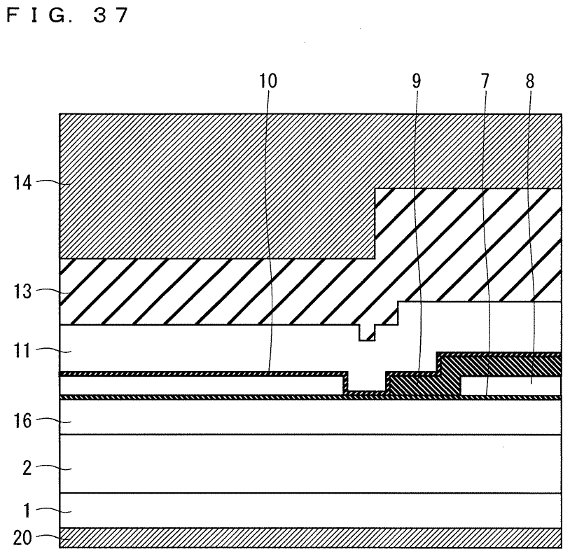

Furthermore, a metal film made of Ni, for example, as a main component is formed on the back surface of the semiconductor substrate 1, and anneal processing is performed to form the back surface ohmic electrode 20. Herein, it is sufficient that a heating temperature in each anneal processing is approximately equal to or higher than 600° C. and equal to or smaller than 1100° C. Accordingly, states in FIG. 30 and FIG. 37 are achieved.

Then, a metal film of aluminum, for example, is formed on the interlayer insulating film 13 and the front surface ohmic electrode 19 and inner sides of the potential fixing layer connection contact hole 27 and the gate contact hole 28 by sputtering method or evaporation method, for example, and a resist mask is formed on the metal film by photolithography processing. Subsequently, patterning is performed on the metal film by etching to form the front surface electrode 14, the gate wiring electrode 15, and the gate electrode pad 29, and then the resist mask is removed.

Finally, the back surface electrode 21 is formed on the back surface ohmic electrode 20 by sputtering method or evaporation method, for example, and the structure of the semiconductor device illustrated in FIG. 22 and FIG. 23 is completed.

Although described in the embodiment 2 is the example of separating the potential fixing layer 8 in the active region 50 and the potential fixing layer 8 in the terminal region 60 by etching so that the potential fixing layer 8 in the active region 50 has the floating potential, in a case where the potential fixing layer 8 in the terminal region 60 is not connected to an external electrode but has the floating potential as described in the embodiment 4, the potential fixing layer 8 in the active region 50 and the potential fixing layer 8 in the terminal region 60 may be connected to each other.

The effect similar to that of the embodiment 1 can be obtained also in the semiconductor device according to the embodiment 2. The thickness of the underlay insulating film 7 formed on the bottom surface of the gate trench 22 is larger than that of the gate insulating film 10, and the gate electrode layer 11 is not located on the bottom surface of the gate trench 22. Thus, reduced is influence of the electrical field occurring in the insulating film (silicon dioxide, for example) on the bottom surface of the gate trench 22 by the drain voltage or the gate voltage in the semiconductor device in the OFF state compared with a case where only the gate insulating film 10 is formed on the bottom surface of the gate trench 22.

### Embodiment 3

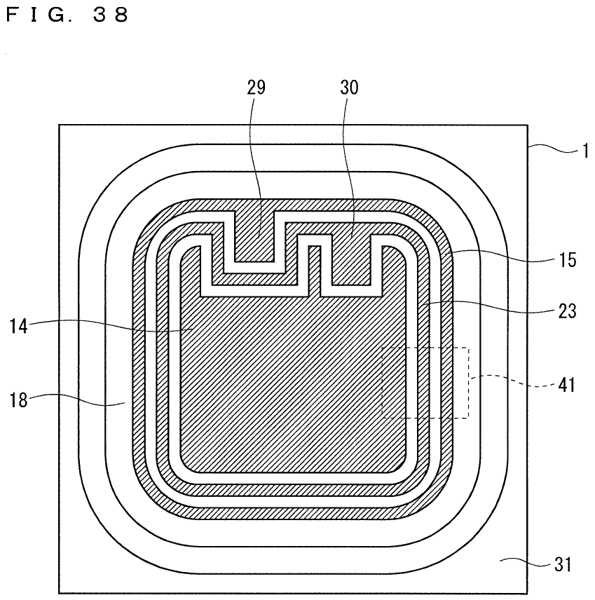

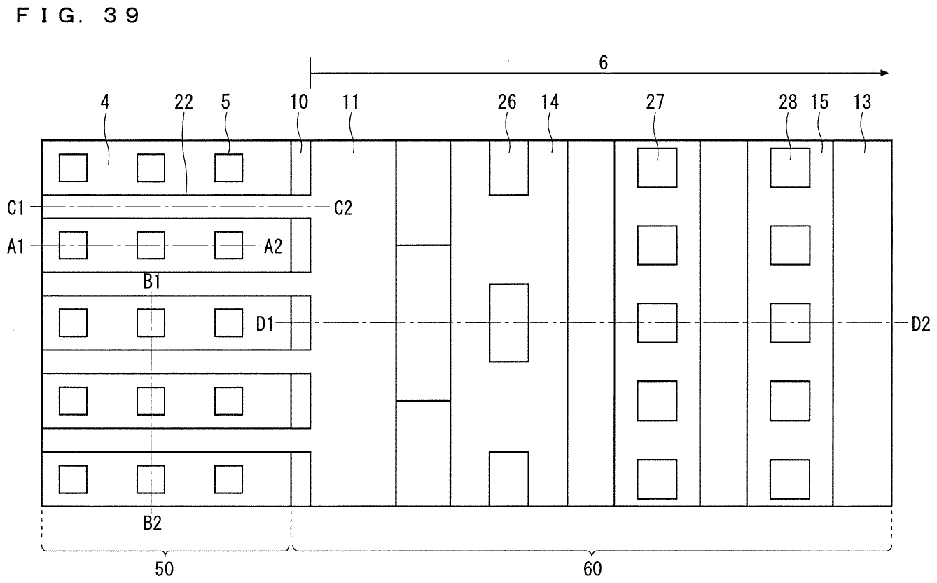

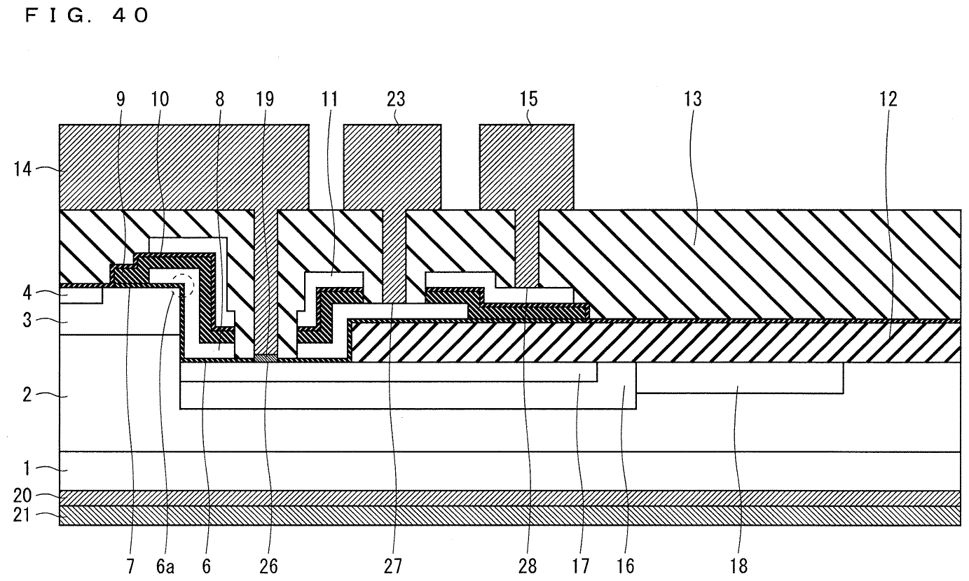

FIG. 38 to FIG. 40 are diagrams each illustrating a configuration of a semiconductor device according to an embodiment 3. FIG. 38 is a schematic plan view illustrating a schematic configuration of the semiconductor device according to the embodiment 3, and FIG. 39 illustrates a configuration of a region 41 surrounded by a broken line in FIG. 38. FIG. 40 is a cross-sectional view along the D1-D2 line in FIG. 39. Illustration of the interlayer insulating film 13, the front surface electrode 14, and the front surface ohmic electrode 19, for example, is omitted for simplifying the description in FIG. 39.

The semiconductor device according to the embodiment 3 includes a ground electrode pad 30 to which ground potential of 0V is supplied and a ground wiring electrode 23 connected thereto. Described in the embodiments 1 and 2 is the example that the potential fixing layer 8 is connected to the front surface electrode 14, and the potential of the potential fixing layer 8 is the source potential. In the embodiment 3, the potential fixing layer 8 is connected to the ground wiring electrode 23, and the potential of the potential fixing layer 8 is set to ground potential. The other configurations are similar to those in the embodiment 1.

Also in a case where the potential fixing layer 8 has the ground potential, the gate insulating film 10 is formed to be isolated from the outer trench upper end corner part 6a in the terminal region 60; thus, the electrical field concentration caused by the shape of the outer trench upper end corner part 6a is suppressed, and breakdown of the gate insulating film 10 is prevented. Although the outer trench upper end corner part 6a is covered by the underlay insulating film 7, the well region 3 has the source potential and the potential fixing layer 8 has the ground potential, and moreover, the potential fixing layer 8 is insulated from the gate electrode layer 11 by the insulating layer 9 and the gate insulating film 10; thus, the underlay insulating film 7 of the outer trench upper end corner part 6a is not broken by the gate voltage.

### Embodiment 4

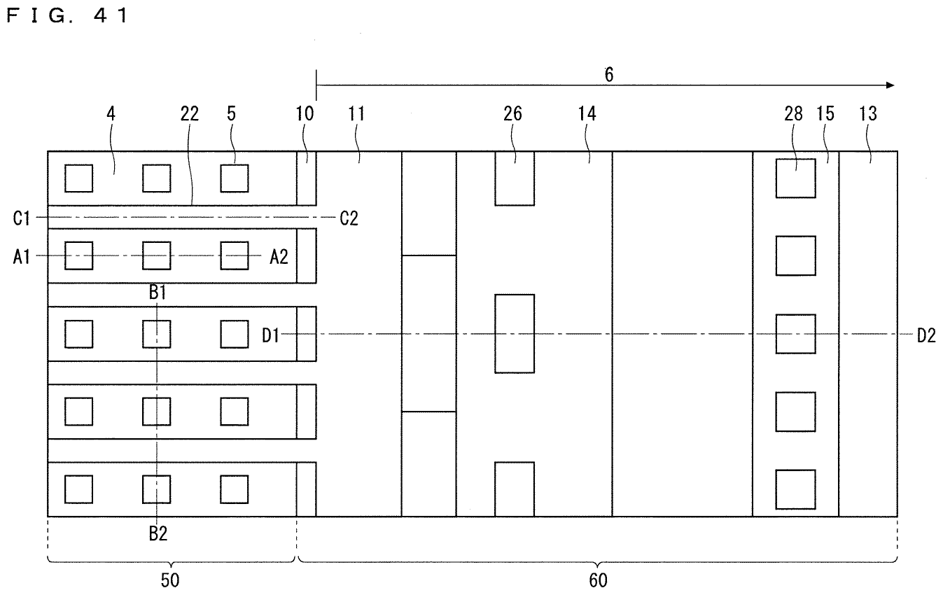

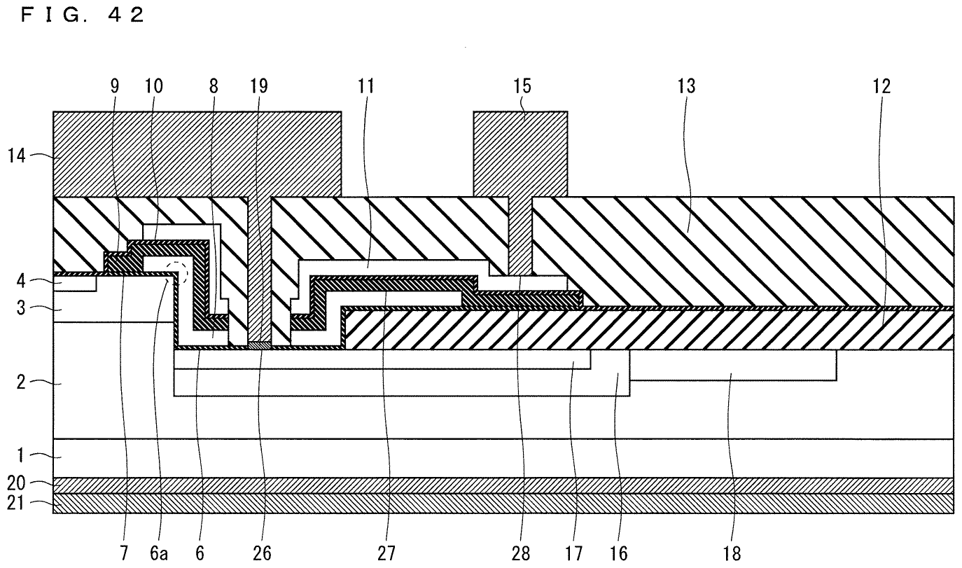

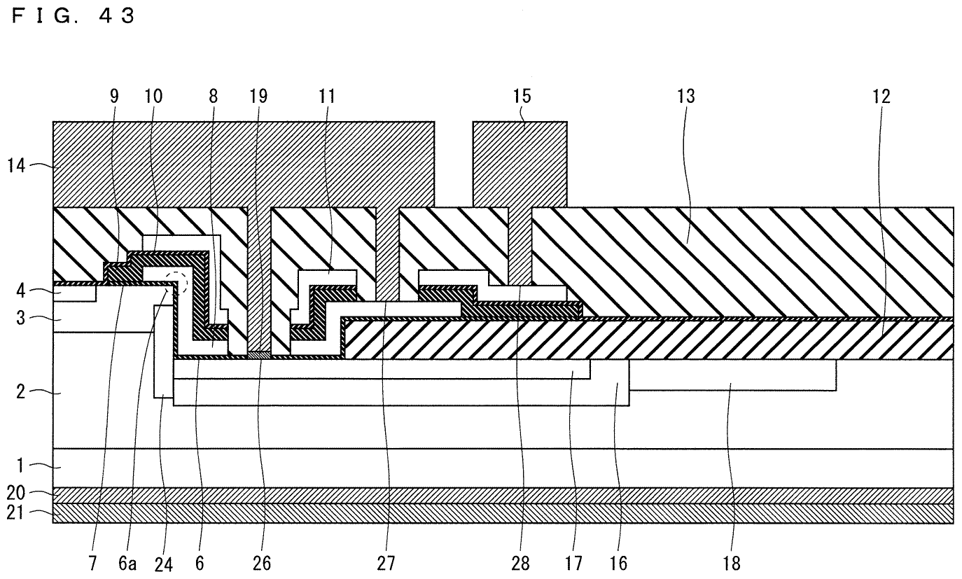

FIG. 41 and FIG. 42 are diagrams each illustrating a configuration of a semiconductor device according to an embodiment 4. FIG. 41 is a schematic view illustrating a schematic configuration of the semiconductor device according to the embodiment 4, and illustrates a configuration of the region 40 surrounded by the broken line in FIG. 1. FIG. 42 is a cross-sectional view along the D1-D2 line in FIG. 41. Illustration of the interlayer insulating film 13, the front surface electrode 14, and the front surface ohmic electrode 19, for example, is omitted for simplifying the description in FIG. 41.

In the embodiment 4, the potential fixing layer connection contact hole 27 is not formed in the interlayer insulating film 13, and the potential fixing layer 8 is not connected to any other electrode. That is to say, the potential of the potential fixing layer 8 is set to floating potential. The other configurations are similar to those in the embodiments 1 to 3.

Also in a case where the potential fixing layer 8 has the floating potential, the gate insulating film 10 is formed to be isolated from the outer trench upper end corner part 6a in the terminal region 60; thus, the electrical field concentration caused by the shape of the outer trench upper end corner part 6a is suppressed, and breakdown of the gate insulating film 10 is prevented. Although the outer trench upper end corner part 6a is covered by the underlay insulating film 7, the well region 3 has the source potential and the potential fixing layer 8 has the ground potential, and moreover, the potential fixing layer 8 is insulated from the gate electrode layer 11 by the insulating layer 9 and the gate insulating film 10; thus, the underlay insulating film 7 of the outer trench upper end corner part 6a is not broken by the gate voltage.

### Embodiment 5

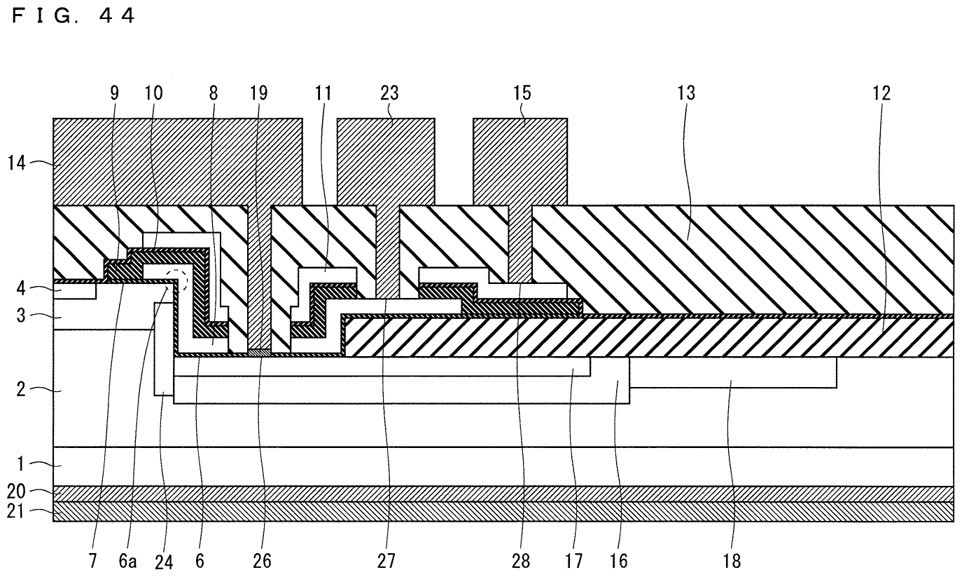

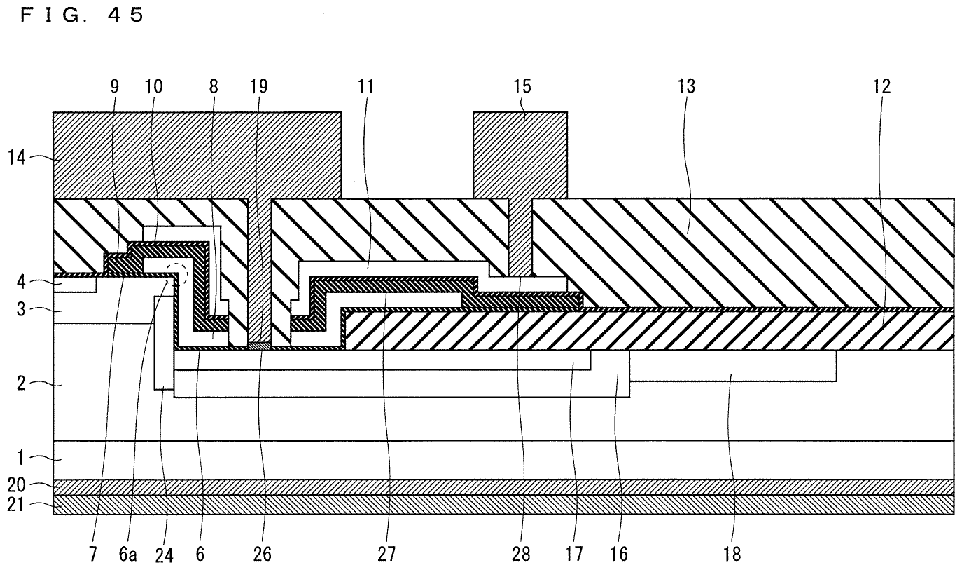

FIG. 43 to FIG. 45 are diagrams each illustrating a configuration of a semiconductor device according to an embodiment 5. FIG. 43 is a cross-sectional view along the D1-D2 line in FIG. 2, FIG. 44 is a cross-sectional view along the D1-D2 line in FIG. 39, and FIG. 45 is a cross-sectional view along the D1-D2 line in FIG. 41.

Described in the embodiments 1 to 4 is the example that the well region 3 and the trench bottom surface electrical field relaxation region 16 are isolated from each other in the terminal region 60. In the embodiment 5, the well region 3 and the trench bottom surface electrical field relaxation region 16 are connected to each other by a p-type outer trench side surface connection layer 24 formed on a side surface of the outer trench 6. The other configurations are similar to those in the embodiments 1 to 4. FIG. 43 corresponds to the configuration in FIG. 6 to which the outer trench side surface connection layer 24 is provided, FIG. 44 corresponds to the configuration in FIG. 40 to which the outer trench side surface connection layer 24 is provided, and FIG. 45 corresponds to the configuration in FIG. 42 to which the outer trench side surface connection layer 24 is provided.

It is sufficient that the outer trench side surface connection layer 24 is formed by ion implantation after forming the trench bottom surface electrical field relaxation region 16, a p-type impurity is aluminum, boron, or gallium, and an impurity concentration is approximately equal to or larger than 1×1017 cm⁻³ and equal to or smaller than 1×1022cm-3, for example.

When the well region 3 and the trench bottom surface electrical field relaxation region 16 are connected in the side surface of the outer trench 6, a route of displacement current occurring in a turning off operation and flowing to the front surface electrode 14 is increased. Thus, suppressed is increase of the potential of the underlay insulating film 7 at the outer trench upper end corner part 6a caused by the displacement current, and breakdown of the underlay insulating film 7 is prevented.

### Embodiment 6

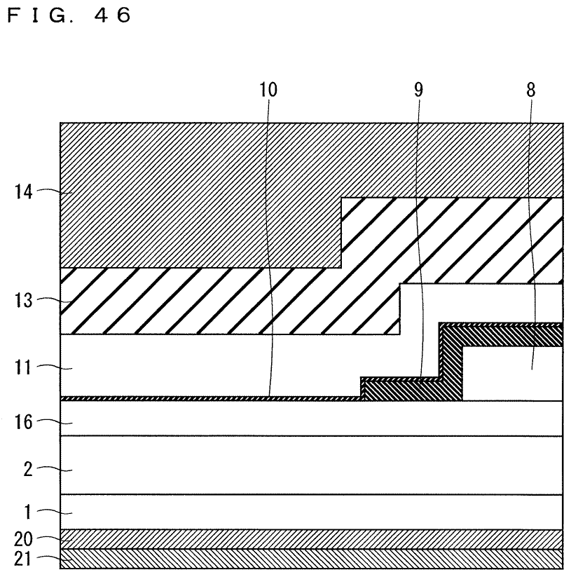

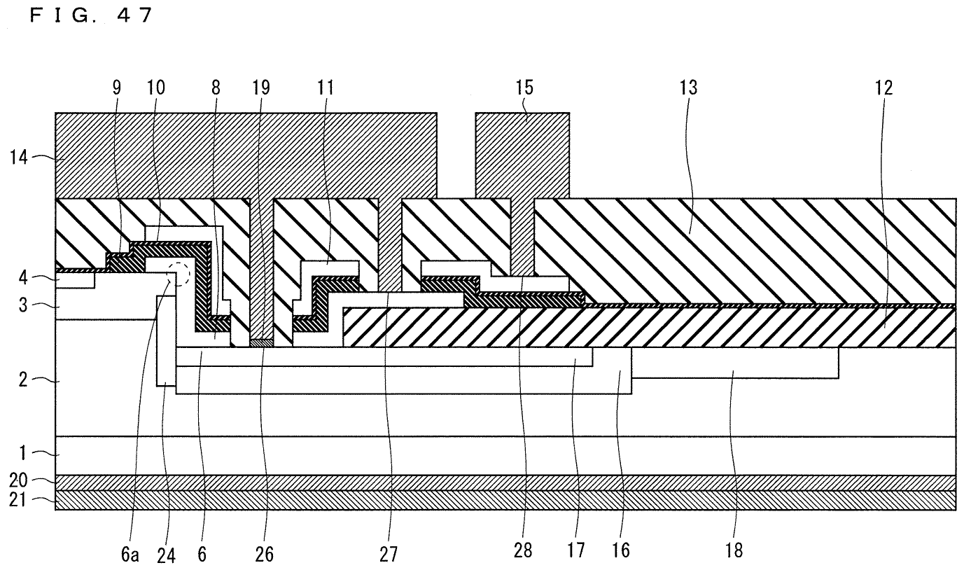

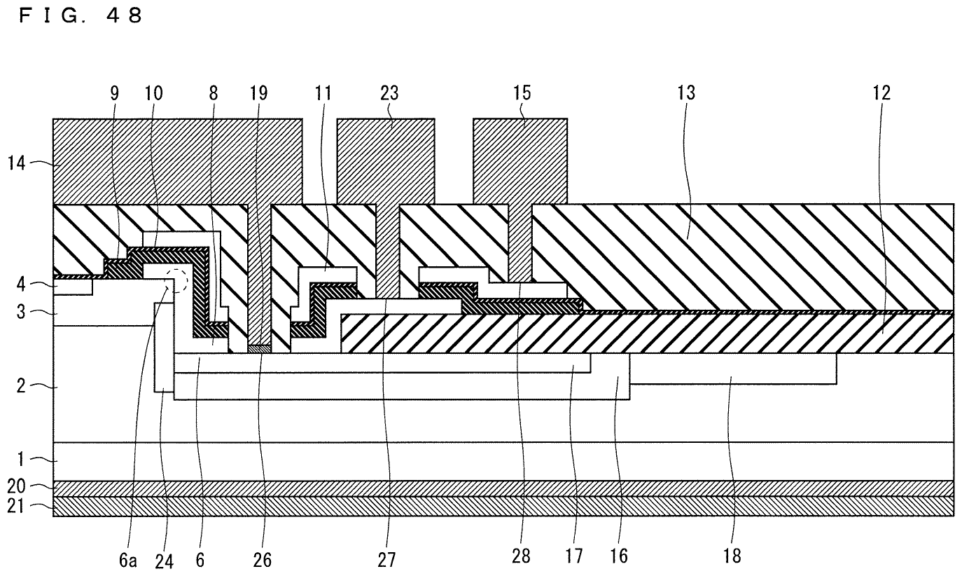

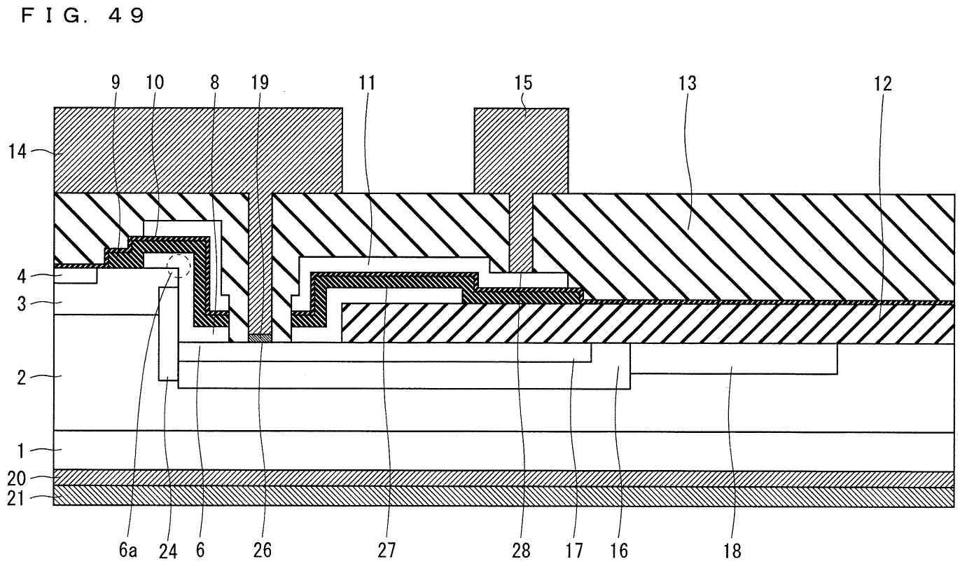

FIG. 46 to FIG. 49 are diagrams each illustrating a configuration of a semiconductor device according to an embodiment 5. FIG. 46 is a cross-sectional view along the B1-B2 line in FIG. 2, FIG. 39, or FIG. 41, FIG. 47 is a cross-sectional view along the D1-D2 line in FIG. 2, FIG. 48 is a cross-sectional view along the D1-D2 line in FIG. 39, and FIG. 49 is a cross-sectional view along the D1-D2 line in FIG. 41.

In the embodiment 6, the underlay insulating film 7 is not formed, but the potential fixing layer 8 has contact with the inner surface of the outer trench 6 and the outer trench upper end corner part 6a. The other configurations are similar to those in the embodiments 1 to 5. FIG. 47 corresponds to the configuration in FIG. 43 from which the underlay insulating film 7 is omitted, FIG. 48 corresponds to the configuration in FIG. 44 from which the underlay insulating film 7 is omitted, and FIG. 49 corresponds to the configuration in FIG. 45 from which the underlay insulating film 7 is omitted.

Also in a case where the underlay insulating film 7 is omitted, the gate insulating film 10 is formed to be isolated from the outer trench upper end corner part 6a in the terminal region 60; thus, the electrical field concentration caused by the shape of the outer trench upper end corner part 6a is suppressed, and breakdown of the gate insulating film 10 is prevented.

In the manner similar to the embodiments 1 to 5, the potential of the potential fixing layer 8 is set to any of the source potential, the ground potential, and the floating potential. Even when the potential of the potential fixing layer 8 is the source potential or the ground potential, current hardly flows from the back surface electrode 21 to the potential fixing layer 8 by influence of a PN junction between the drift layer 2 and the well region 3, the outer trench side surface connection layer 24, the trench bottom surface electrical field relaxation region 16, and the trench bottom surface high concentration well region 17, and there is little influence on loss.

Each embodiment can be arbitrarily combined, or each embodiment can be appropriately varied or omitted.

The foregoing description is in all aspects illustrative, and is therefore understood that numerous modification examples not illustrated can be devised.

### EXPLANATION OF REFERENCE SIGNS

1 semiconductor substrate, 2 drift layer, 3 well region, 4 impurity region, 5 contact region, 6 outer trench, 6a outer trench upper end corner part, 7 underlay insulating film, 8 potential fixing layer, 9 insulating layer, 10 gate insulating film, 11 gate electrode layer, 12 field insulating layer, 13 interlayer insulating film, 14 front surface electrode, 15 gate wiring electrode, 16 trench bottom surface electrical field relaxation region, 17 trench bottom surface high concentration well region, 18 terminal electrical field relaxation region, 19 front surface ohmic electrode, 20 back surface ohmic electrode, 21 back surface electrode, 22 gate trench, 22a gate trench upper end corner part, 23 ground wiring electrode, 24 outer trench side surface connection layer, 25 source contact hole, 26 outer surrounding part well region contact hole, 27 potential fixing layer connection contact hole, 28 gate contact hole, 29 gate electrode pad, 30 ground electrode pad, 31 channel stop region, 50 active region, 60 terminal region.

1. A semiconductor device, comprising:
a drift layer of a first conductivity type;
a well region of a second conductivity type formed on a surface portion of the drift layer;
an impurity region of a first conductivity type formed on a surface portion of the well region;
a gate trench passing through the impurity region and the well region in an active region to reach the drift layer;
a gate insulating film formed to have contact with an inner surface of the gate trench;
a gate electrode film formed on the gate insulating film;
an interlayer insulating film covering the gate electrode layer;
a gate wiring electrode formed on the interlayer insulating film and connected to the gate electrode layer;
an outer trench formed in the drift layer in a terminal region on an outer side of the active region;
a potential fixing layer formed in the outer trench to cover an upper end corner part of the outer trench;
an insulating film formed on the potential fixing layer; and
an underlay insulating film formed below the potential fixing layer, wherein
the gate insulating film and the gate electrode film extend to an inner side of the outer trench of the terminal region, and the gate electrode layer is connected to the gate wiring electrode through a contact hole formed in the interlayer insulating film in the outer trench, and
the underlay insulating film is uniformly formed along inner surfaces of the gate trench and the outer trench without an opening through which the potential fixing layer is exposed.

2. The semiconductor device according to claim 1, wherein
the potential fixing layer has a thickness larger than a thickness of the gate insulating film.

3. (canceled)

4. The semiconductor device according to claim 1, wherein
a thickness of the underlay insulating film is equal to or larger than a thickness of the gate insulating film.

5. The semiconductor device according to claim 1, wherein
a part of the potential fixing layer is formed on a bottom part of the gate trench, and the gate insulating film and the gate electrode layer in the gate trench is formed on the potential fixing layer, and
the potential fixing layer on the bottom part of the gate trench is formed to have floating potential.

6. The semiconductor device according to claim 1, further comprising:
a trench bottom surface electrical field relaxation region of a second conductivity type formed on a lower side of the outer trench; and
an outer trench side surface connection layer of a second conductivity type formed on a side surface of the outer trench and connecting the well region and the trench bottom surface electrical field relaxation region.

7. The semiconductor device according to claim 1, further comprising
a front surface electrode formed on the interlayer insulating film and connected to the well region, wherein
the potential fixing layer is connected to the front surface electrode through a contact hole formed in the interlayer insulating film.

8. The semiconductor device according to claim 1, further comprising
a ground wiring electrode formed on the interlayer insulating film, wherein
the potential fixing layer is connected to the ground wiring electrode through a contact hole formed in the interlayer insulating film.

9. The semiconductor device according to claim 1, wherein
the potential fixing layer is formed to have floating potential.

10. The semiconductor device according to claim 1, wherein
the gate electrode layer in the terminal region surrounds the gate trench in a plan view.

11. The semiconductor device according to claim 1, wherein
a thickness of the potential fixing layer is three times or more as large as the thickness of the gate insulating film.

12. The semiconductor device according to claim 1, wherein
a thickness of the insulating layer is equal to or larger than the thickness of the gate insulating film.

13. The semiconductor device according to claim 1, wherein
an upper end of the gate electrode layer of the gate trench is located in a position lower than an upper end of the gate trench.

14. A method of manufacturing a semiconductor device, comprising:
forming a drift layer of a first conductivity type;
forming a well region of a second conductivity type on a surface portion of the drift layer;
forming an impurity region of a first conductivity type on a surface portion of the well region;
forming a gate trench passing through the impurity region and the well region in an active region to reach the drift layer;
forming an outer trench in the drift layer in a terminal region on an outer side of the active region;
forming a potential fixing layer in the outer trench to cover an upper end corner part of the outer trench;
of forming an insulating film on the potential fixing layer;
forming a gate insulating film in the gate trench and the outer trench;
forming a gate electrode layer on the gate insulating film in the gate trench and the outer trench;
of forming an interlayer insulating film covering the gate electrode layer;
forming a contact hole reaching the gate electrode layer in the interlayer insulating film in the outer trench; and
forming a gate wiring electrode connected to the gate electrode layer through the contact hole on the interlayer insulating film, the method of manufacturing the semiconductor device further comprising
forming an underlay insulating film provided below the potential fixing layer before forming the potential fixing layer, wherein
the underlay insulating film is uniformly formed along inner surfaces of the gate trench and the outer trench without an opening through which the potential fixing layer is exposed.

15. The method of manufacturing the semiconductor device according to claim 14, wherein
the potential fixing layer is formed to have a thickness larger than a thickness of the gate insulating film.

16. (canceled)

17. The method of manufacturing the semiconductor device according to claim 14, wherein
a part of the potential fixing layer is formed in the gate trench in forming the potential fixing layer.
